(19) United States
(12) Patent Application Publication
(10) Pub. No.: US 2026/0126501 A1
(43) Pub. Date: May 7, 2026

(54) ELECTRICAL MEASUREMENT METHODS, SYSTEMS, AND KITS

(71) Applicant: Power Probe Group, Inc., Charlotte, NC (US)

(72) Inventor: David Douglas Barden, Crestline, CA (US)

(73) Assignee: Power Probe Group, Inc., Charlotte, NC (US)

(21) Appl. No.: 18/936,829

(22) Filed: Nov. 4, 2024

(51) Int. Cl. G01R 31/74; G01R 1/067; G01R 19/15; G01R 19/25; G01R 27/16; G01R 31/54

(52) U.S. Cl. CPC G01R 31/74; G01R 1/0675; G01R 1/06788; G01R 19/15; G01R 19/2513; G01R 27/16; G01R 31/54

(57) ABSTRACT

Electrical testing methods, systems, and kits are capable of powering, via a first power supply, an electrical system, performing, via a first electrical device, selective detection of at least two parameters of the electrical system, and detecting, via sensor(s) of a second electrical device, presence and/or flow of a parameter from a second power supply to the electrical system to derive parasitic draw of the electrical system. Memory settings of the electrical system are preserved via the second electrical device while the parasitic draw is derived. User input(s) selecting an electrical element of the electrical system are received via a third electrical device that stores impedance data of electrical elements. The third electrical device determines voltage drop across an electrical path passing through the electrical element, which the third electrical device uses to determine, in combination with the impedance identified by the impedance data, amperage of the electrical element.

### FIELD OF THE INVENTION

This invention relates generally to electrical testing, and more particularly, embodiments of the invention relate to an electrical testing methods, systems, and kits.

### BACKGROUND OF THE INVENTION

Motor vehicles such as automobiles and trucks are becoming increasingly technologically sophisticated requiring a correspondingly more sophisticated set of test equipment for maintenance and diagnostic testing. Much of the increased complexity of motor vehicles is due in part to the increased complexity of electrical circuitry and systems incorporated therein. Troubleshooting and diagnosing problems with such electrical systems requires the use of a wide array of complex test equipment. Vehicle technicians use devices and approaches that may have limited applicability to certain vehicle diagnostics and monitoring. In particular, these devices and approaches may not provide the most relevant information or such devices and approaches may be inefficient.

Thus, a need exists for improved methods, systems, and kits for resolving these deficiencies and inefficiencies.

### BRIEF SUMMARY

Shortcomings of the prior art are overcome, and additional advantages are provided, through the provision of an electrical testing method that includes powering, via a first power supply, an electrical system, and based thereon performing, via a first electrical device, selective detection of at least two parameters of the electrical system, the powering being selectively provided during detection of the at least two parameters. The first electrical device includes a probe element that is configured to be placed into contact with the electrical system and provide an input signal thereto. The first electrical device also includes a processor electrically connected to the conducting probe element and configured to (a) manipulate the input signal provided to the electrical system, and (b) receive an output signal representative of one or more parameters of the at least two parameters of the electrical system. The method also includes detecting, via one or more sensors of a second electrical device and based on the second electrical device being coupled to the electrical system, presence of at least one parameter and/or flow of the at least one parameter from a second power supply to the electrical system, the second electrical device including an analyzer electrically coupled to the one or more sensors and configured to derive parasitic draw of the electrical system based on the detection of the at least one parameter. In addition, the method includes deriving, via the analyzer of the second electrical device, the parasitic draw of the electrical system from the parameter flowing from the second power supply to the electrical system, and receiving, by a third electrical device, one or more user inputs selecting an electrical element from a list of electrical elements, each electrical element of the list of electrical elements having an impedance associated therewith. The method also includes accessing, from a data storage location associated with the third electrical device, impedance data of the electrical element's impedance, and determining, via the third electrical device, voltage drop across an in-circuit electrical path passing through the electrical element. The method also determines, via the third electrical device and from the voltage drop and the impedance, amperage of the electrical element.

An electrical testing method is disclosed that includes using a first electrical device to detect at least two parameters of an electrical system, where the first electrical device includes a probe element that is configured to be placed into contact with the electrical system and provide an input signal thereto and a processor electrically connected to the conducting probe element and configured to (a) manipulate the input signal provided to the electrical system, and (b) receive an output signal representative of one or more parameters of the at least two parameters of the electrical system. The method also includes using a second electrical device to (i) preserve memory settings of the electrical system, and (ii) derive any parasitic draw within the electrical system. In addition, the method includes using a third electrical device to derive amperage of an electrical element of the electrical system, the deriving determing voltage drop across an in-circuit electrical path passing through the electrical element and accessing impedance data of the electrical element to calculate from the voltage drop and the impedance data amperage of the electrical element.

Also disclosed herein is an electrical testing system that includes a first electrical device to detect at least two parameters of an electrical system, the first electrical device comprising a probe element that is configured to be placed into contact with the electrical system and provide an input signal thereto, and a processor electrically connected to the conducting probe element and configured to (a) manipulate the input signal provided to the electrical system, and (b) receive an output signal representative of one or more parameters of the at least two parameters of the electrical system. The system also includes a second electrical device for (i) preserving memory settings of the electrical system, and (ii) deriving any parasitic draw within the electrical system, the second electrical device comprising a power supply for providing power to the electrical system, which enables the second electrical device to maintain memory of electrical system settings during disconnect of a power source of the electrical system, and one or more sensors for detecting a parameter flowing from the power supply of the second electrical device to the electrical system. The second electrical device also includes an analyzer electrically coupled to the one or more sensors and configured to derive parasitic draw of the electrical system based on the detection of the parameter. The system also includes a third electrical device for determining amperage of an electrical element of the electrical system, the third electrical device comprising a first conductive probe element, a second conductive probe element, a processor in electrical communication with the first conductive probe element and the second conductive probe element, and a data storage location storing impedance data for a list of electrical elements, the list of electrical elements including the electrical element of the electrical system.

In addition, an electrical testing kit is disclosed that includes a first electrical device to detect at least two parameters of an electrical system, the first electrical device comprising a probe element that is configured to be placed into contact with the electrical system and provide an input signal thereto and connected to the conducting probe element and configured to (a) manipulate the input signal provided to the electrical system, and (b) receive an output signal representative of one or more parameters of the at least two parameters of the electrical system. The kit also includes a second electrical device for (i) preserving memory settings of the electrical system, and (ii) deriving any parasitic draw within the electrical system. The second electrical device comprises a power supply for providing power to the electrical system, which enables the second electrical device to maintain memory of electrical system settings of the electrical system during disconnect of a power source of the electrical system, one or more sensors for detecting presence of at least one parameter and/or flow of the at least one parameter from the power supply of the second electrical device to the electrical system, and an analyzer electrically coupled to the one or more sensors and configured to derive parasitic draw of the electrical system based on the detection of the at least one parameter. The kit also includes a third electrical device for determining amperage of an electrical element of the electrical system. The third electrical device includes a first conductive probe element, a second conductive probe element, a processor in electrical communication with the first conductive probe element and the second conductive probe element, and a data storage location storing impedance data for a list of electrical elements, the list of electrical elements including the electrical element of the electrical system.

Additional features and advantages are realized through the concepts described herein.

### BRIEF DESCRIPTION OF THE DRAWINGS

One or more aspects are particularly pointed out and distinctly claimed as examples in the claims at the conclusion of the specification. The foregoing as well as objects, features, and advantages of one or more aspects are apparent from the following detailed description taken in conjunction with the accompanying drawings in which:

FIG. 1 is a block diagram of an electrical test device that illustrates a power supply, a microprocessor, a display device, a keypad, and an energizable probe element that make up the electrical test device, according to an implementation of the present disclosure;

FIG. 2 is a perspective view of the electrical test device and illustrating a pair of power leads and a ground lead connected to a circuit board of the electrical test device, according to an implementation of the present disclosure;

FIG. 3 is a partially exploded perspective view of the electrical test device illustrating a housing comprising upper and lower shells, a circuit board assembly contained within the housing, and the power cable and probe element extending out of the housing, according to an implementation of the present disclosure;

FIG. 4 is a top view of the electrical test device illustrating a keypad, a plurality of signal lamps, and speaker holes formed within the upper shell as well as an auxiliary cable connectable to the electrical test device, according to an implementation of the present disclosure;

FIG. 5 is an end view of the electrical test device illustrating illuminating lamps, and an auxiliary jack formed within the housing for receiving the auxiliary cable, according to an implementation of the present disclosure;

FIG. 6 depicts a front view of an electrical test device, according to an implementation of the present disclosure;

FIG. 7 depicts the front interior on the driver's side of a vehicle with a magnified view of a vehicle diagnostic port and an example apparatus for preserving memory settings and deriving parasitic draw of an electrical system of a vehicle, according to an implementation of the present disclosure;

FIG. 8A illustrates a perspective view of an example apparatus for preserving memory settings and deriving parasitic draw of an electrical system of a vehicle, according to an implementation of the present disclosure;

FIG. 8B illustrates a front elevational view of an example apparatus for preserving memory settings and deriving parasitic draw of an electrical system of a vehicle, according to an implementation of the present disclosure;

FIG. 8C illustrates bottom plan view of an example apparatus for preserving memory settings and deriving parasitic draw of an electrical system of a vehicle, according to an implementation of the present disclosure;

FIG. 8D illustrates a left side elevational view of an example apparatus for preserving memory settings and deriving parasitic draw of an electrical system of a vehicle, according to an implementation of the present disclosure;

FIG. 8E illustrates a back elevational view of an example apparatus for preserving memory settings and deriving parasitic draw of an electrical system of a vehicle, according to an implementation of the present disclosure;

FIG. 9A depicts a front elevational view of an apparatus for preserving memory settings and deriving parasitic draw of an electrical system of a vehicle, according to an implementation of the present disclosure;

FIG. 9B depicts a front elevational view of an example apparatus for preserving memory settings and deriving parasitic draw of an electrical system of a vehicle, according to an implementation of the present disclosure;

FIG. 10 depicts an example system for preserving memory settings and deriving parasitic draw of an electrical system of a vehicle, according to an implementation of the present disclosure;

FIG. 11 depicts a block diagram of an example method for preserving memory settings and deriving parasitic draw of an electrical system of a vehicle, according to an implementation of the present disclosure;

FIG. 12 is a perspective view of an electrical testing device, in accordance with an embodiment of the present invention;

FIG. 13 is another perspective view of the electrical testing device of FIG. 12, in accordance with an embodiment of the present invention;

FIG. 14 is a top view of the electrical testing device of FIGS. 12-13, in accordance with an embodiment of the present invention;

FIG. 15A depicts a portion of a fuse voltage drop chart for a standard fuse, according to one embodiment of the present invention;

FIG. 15B depicts another portion of the fuse voltage drop chart of FIG. 15A, according to one embodiment of the present invention;

FIG. 16A depicts a portion of a fuse voltage drop chart of a mini fuse, according to one embodiment of the present invention;

FIG. 16B depicts a portion of the fuse voltage drop chart of FIG. 16A, according to one embodiment of the present invention;

FIG. 17A depicts a portion of a fuse voltage drop chart of a maxi fuse, according to one embodiment of the present invention;

FIG. 17B depicts a portion of the fuse voltage drop chart of FIG. 17A, according to one embodiment of the present invention;

FIG. 18A depicts a portion of a fuse voltage drop chart of a micro fuse, according to one embodiment of the present invention;

FIG. 18B depicts a portion of the fuse voltage drop chart of FIG. 18A, according to one embodiment of the present invention;

FIG. 19A depicts a portion of a fuse voltage drop chart of a JCASE™ cartridge style fuse, according to one embodiment of the present invention;

FIG. 19B depicts a portion of the fuse voltage drop chart of FIG. 19A, according to one embodiment of the present invention;

FIG. 20A depicts a portion of a fuse voltage drop chart of a glass fuse, according to one embodiment of the present invention;

FIG. 20B depicts a portion of the fuse voltage drop chart of FIG. 20A, according to one embodiment of the present invention;

FIG. 21 depicts a block diagram of an example method, according to an implementation of the present disclosure;

FIG. 22A depicts a perspective view of an electrical testing device in combination with a sleeve, according to an implementation of the present disclosure;

FIG. 22B depicts another perspective view of the electrical testing device in combination with the sleeve of FIG. 22A, according to an implementation of the present disclosure;

FIG. 22C depicts another perspective view of the electrical testing device in combination with the sleeve of FIGS. 22A-22B, according to an implementation of the present disclosure;

FIG. 22D depicts another perspective view of the electrical testing device in combination with the sleeve of FIG. 22A-22C, according to an implementation of the present disclosure;

FIG. 22E depicts another perspective view of the electrical testing device in combination with the sleeve of FIG. 22A-22D, according to an implementation of the present disclosure;

FIG. 22F depicts another perspective view of the electrical testing device in combination with the sleeve of FIG. 22A-22E, according to an implementation of the present disclosure;

FIG. 22G depicts another perspective view of the electrical testing device in combination with the sleeve of FIG. 22A-22F, according to an implementation of the present disclosure;

FIG. 22H depicts another perspective view of the electrical testing device in combination with the sleeve of FIG. 22A-22G, according to an implementation of the present disclosure;

FIG. 22I depicts a side view of the electrical testing device in combination with the sleeve of FIG. 22A-22H, according to an implementation of the present disclosure;

FIG. 22J depicts a back view of the electrical testing device in combination with the sleeve of FIG. 22A-22I, according to an implementation of the present disclosure;

FIG. 22K depicts a side view of the electrical testing device in combination with the sleeve of FIG. 22A-22J, according to an implementation of the present disclosure;

FIG. 22L depicts a front view of the electrical testing device in combination with the sleeve of FIG. 22A-22K, according to an implementation of the present disclosure;

FIG. 22M depicts a top view of the electrical testing device in combination with the sleeve of FIG. 22A-22L, according to an implementation of the present disclosure;

FIG. 22N depicts a bottom view of the electrical testing device in combination with the sleeve of FIG. 22A-22M, according to an implementation of the present disclosure;

FIG. 23A depicts a perspective view of an electrical testing device, according to an implementation of the present disclosure;

FIG. 23B depicts another perspective view of the electrical testing device of FIG. 23A, according to an implementation of the present disclosure;

FIG. 23C depicts another perspective view of the electrical testing of FIGS. 23A-23B, according to an implementation of the present disclosure;

FIG. 23D depicts another perspective view of the electrical testing device of FIG. 23A-23C, according to an implementation of the present disclosure;

FIG. 23E depicts another perspective view of the electrical testing device of FIG. 23A-23D, according to an implementation of the present disclosure;

FIG. 23F depicts another perspective view of the electrical testing device of FIG. 23A-23E, according to an implementation of the present disclosure;

FIG. 23G depicts another perspective view of the electrical testing device of FIG. 23A-23F, according to an implementation of the present disclosure;

FIG. 23H depicts another perspective view of the electrical testing device of FIG. 23A-23G, according to an implementation of the present disclosure;

FIG. 23I depicts a side view of the electrical testing device of FIG. 23A-23H, according to an implementation of the present disclosure;

FIG. 23J depicts a back view of the electrical testing device of FIG. 23A-23I, according to an implementation of the present disclosure;

FIG. 23K depicts a side view of the electrical testing device of FIG. 23A-23J, according to an implementation of the present disclosure;

FIG. 23L depicts a front view of the electrical testing device of FIG. 23A-23K, according to an implementation of the present disclosure;

FIG. 23M depicts a top view of the electrical testing device of FIG. 23A-23L, according to an implementation of the present disclosure; and

FIG. 23N depicts a bottom view of the electrical testing device of FIG. 23A-23M, according to an implementation of the present disclosure.

### DETAILED DESCRIPTION

Aspects of the present invention and certain features, advantages, and details thereof are explained more fully below with reference to the non-limiting examples illustrated in the accompanying drawings. It is to be understood that the disclosed embodiments are merely illustrative of the present invention and the invention may take various forms. Further, the figures are not necessarily drawn to scale, as some features may be exaggerated to show details of particular components. Thus, specific structural and functional details illustrated herein are not to be interpreted as limiting, but merely as a representative basis for teaching one skilled in the art to employ the present invention.

Descriptions of well-known processing techniques, systems, components, etc. may be omitted to not unnecessarily obscure the invention in detail. It should be understood that the detailed description and the specific examples, while indicating aspects of the invention, are given by way of illustration only, and not by way of limitation. Various substitutions, modifications, additions, and/or arrangements, within the spirit and/or scope of the underlying inventive concepts will be apparent to those skilled in the art from this disclosure. Additionally, numerous inventive aspects and features are disclosed herein, and unless inconsistent, each disclosed aspect or feature is combinable with any other disclosed aspect or feature as desired for a particular embodiment of the concepts disclosed herein.

The specification may include references to “one embodiment”, “an embodiment”, “various embodiments”, “one or more embodiments”, etc. may indicate that the embodiment(s) described may include a particular feature, structure or characteristic, but every embodiment may not necessarily include the particular feature, structure, or characteristic. In some cases, such phrases are not necessarily referencing the same embodiment. When a particular feature, structure, or characteristic is described in connection with an embodiment, such description can be combined with features, structures, or characteristics described in connection with other embodiments, regardless of whether such combinations are explicitly described.

The terms “couple,” “coupled,” “couples,” “coupling,” and the like should be broadly understood to refer to connecting two or more elements or signals electrically and/or mechanically, either directly or indirectly through intervening circuitry and/or elements. Two or more electrical elements may be electrically coupled, either direct or indirectly, but not be mechanically coupled; two or more mechanical elements may be mechanically coupled, either direct or indirectly, but not be electrically coupled; two or more electrical elements may be mechanically coupled, directly or indirectly, but not be electrically coupled. Coupling (whether only mechanical, only electrical, or both) may be for any length of time, e.g., permanent or semi-permanent or only for an instant. Additionally, “electrically coupled” and the like should be broadly understood and include coupling involving any electrical signal, whether a power signal, a data signal, and/or other types or combinations of electrical signals.

In addition, as used herein, the terms “about,” “approximately,” or “substantially” for any numerical values or ranges indicate a suitable dimensional tolerance that allows the device, part, or collection of components to function for its intended purpose as described herein. As used herein, the term “vehicle” is to be interpreted broadly to include any machine used to transport people or cargo including, for example, motor vehicles (e.g., motorcycles, cars, trucks, buses, mobility scooters, etc.), railed vehicles (e.g., trains, trams, etc.), watercraft (e.g., ships, boats, underwater vehicles, etc.), amphibious vehicles (e.g., hovercraft, screw-propelled vehicles, etc.), aircraft (e.g., airplanes, helicopters, etc.), and spacecraft.

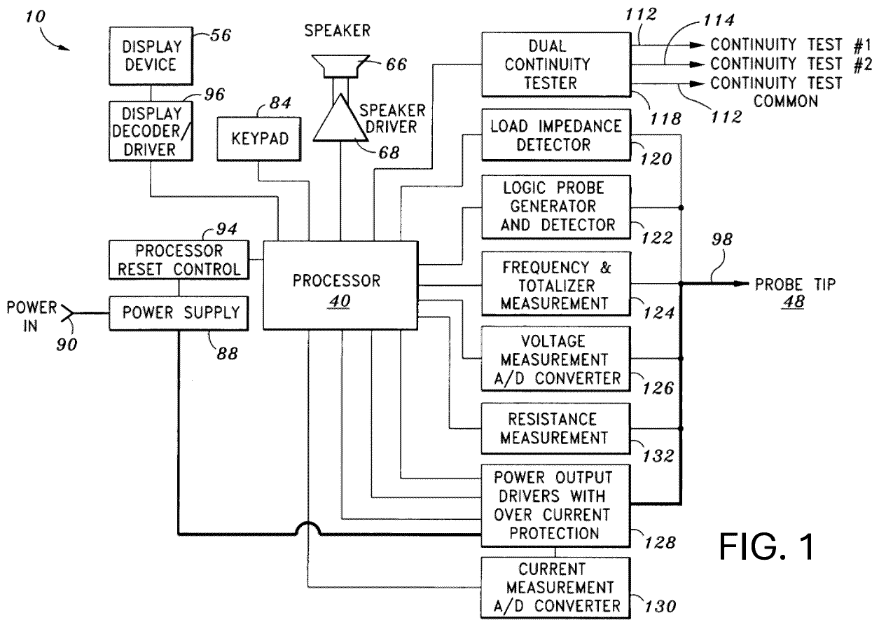

FIG. 1 is a perspective view of an electrical test device 10, in accordance with an embodiment of the present invention that is specifically adapted to provide current sourcing to an electrical system while also providing multi-meter functionality for selective detection and/or measurement of a plurality of parameters of the electrical system, wherein the plurality of parameters of the electrical system include at least two parameters. In one embodiment, the at least two parameters including continuity and voltage. In some embodiments, the at least two parameters may include continuity, voltage, resistance, current, load impedance and/or frequency. Advantageously, the electrical test device 10 is uniquely configured to allow for the collection of data on active, even on relatively high-current, electrical systems.

More specifically, the electrical test device 10 is specifically configured to allow access to current flow through the electrical system and includes the capability to characterize loaded impedance, wave form (e.g., fluctuation, frequency/speed), and current drain in addition to functions commonly performed by multi-meters such as voltage, current and resistance measurements. As was earlier mentioned, the unique configuration of the electrical test device 10 eliminates the need for clip-on current sensors as may be required in prior art electrical test devices. In addition, the unique configuration of the electrical test device 10 eliminates the need for a separate power cable and probe element connection.

In its broadest sense, the electrical test device 10 comprises a conductive probe element 50, a power supply 88, a processor 92 and a display device 54. Importantly, the electrical test device 10 is configured to allow for selective powering of the electrical system under test upon energization of the probe element 50 while parameters of the electrical system are being measured. Referring to FIG. 1, shown is the block diagram of the electrical test device 10. As can be seen, the block diagram illustrates several functional blocks that indicate the various measurement capabilities of the test device 10. Each of the functional blocks is under control of the processor 92 which, as is shown in FIG. 1, may be configured as a microprocessor 40.

Referring now more particularly to FIG. 1, shown is the conductive probe element 50 which is configured to be placed into contact with the electrical system under test. In addition, the conductor probe element 50 is configured to provide an input signal to the electrical system. The power supply 88 is interconnected between an external power source 90 and the probe element 50. The power source may be configured as a battery of a motor vehicle which includes the electrical system under test. However, the external power source 90 may be configured in a variety of embodiments other than a motor vehicle battery.

Referring still to FIG. 1, the power supply 88 is connected to a reset control 94 such as a microprocessor reset control 94. The microprocessor reset control 94 may be comprised of circuitry that provides a reset signal to the processor 92 or microprocessor 40 under conditions wherein the operating voltage may be out of tolerance. As was earlier mentioned, the power supply 88 is connected to the external power source 90. The power supply 88 is preferably configured to provide a voltage regulated output for all circuitry within the electrical test device 10. Preferably, the voltage regulated output is provided independent of any input signal to the electrical system under test.

As can be seen in FIG. 1, the microprocessor reset control 94 is electrically connected to the processor 92 or microprocessor 40. The processor 92 or microprocessor 40 is electrically connected to the probe element 50 and is configured to manipulate the input signal provided to the electrical system and to receive an output signal in response to the input signal. The output signal is representative of the measurement of at least one of the parameters of the electrical system. In manipulating and controlling the electrical test device 10 measurement functions, the processor 92 or microprocessor 40 may be provided with an executable software program configured to provide control of the various measurement processes of the electrical test device 10. In this manner, the processor 92 or microprocessor 40 controls all the functions of the electrical test device 10.

As can be seen in FIG. 1, the electrical test device 10 includes the display device 54, which is electrically connected to the processor 92 or microprocessor 40, and which is configured to display a reading of the output signal which is extracted from the electrical system under test. The reading is representative of the parameter being measured. It should also be noted that an audible device may be included within the electrical test device 10 for providing an audible indication of certain operating parameters of the electrical system under test. For example, the audible device may comprise a piezo element 70 such as a piezo disk 74 which acts as a speaker 66 for providing information regarding continuity measurements and voltage polarity of the electrical system. As was earlier mentioned, the electrical test device 10 is specifically configured to allow for selective powering of the electrical system upon energization of the probe element 50 during measurement of the parameters of the electrical system.

The electrical device may be configured to automatically switch between one of an active mode and a passive mode wherein the active mode is defined by measurement of the parameters of the electrical system during powering thereof. As was previously mentioned, such power is ultimately supplied by an external power source 90 and which is directed through a power supply 88 and passed into the probe element 50. In this manner, the probe element 50 may transfer current into the electrical system under test. The passive mode is defined by measurement of the parameters of the electrical system without the application of power to the electrical system. The application of power may be controlled by a keypad 84 which is illustrated in FIG. 1 as being connected to a processor 92 or microprocessor 40.

In addition, the display device 54 such as a liquid crystal display 56 may be operative to indicate whether the test device 10 is in the passive mode or the active mode. As can be seen in FIG. 1, the electrical test device 10 may include a speaker driver 68 which is connected to the speaker 66 (i.e., the piezo element 70) and which handles the formatting and converting of signals from the processor 92 or microprocessor 40 such that the speaker 66 may be operated as necessary. In the same sense, the display driver 96, shown in FIG. 1 as being connected between the processor 92 or microprocessor 40 and the display device 54, is also operative to format and convert signals from the processor 92 or microprocessor 40 into a format needed for display by the display device 54.

Referring still to FIG. 1, shown are the functional blocks representative of the features of the electrical test device 10. Included with the functional blocks are dual continuity tester 118, load impedance detector 120, logic probe detector and generator 122, frequency and totalizer measurement 124, voltage measurement 126, resistance measurement 132, power output driver 128 with over current protection, and current measurement 130. The voltage measurement 126 functionality and the current measurement 130 functionality may each include analog-to-digital conversion mechanisms. Importantly, due to the unique configuration of the electrical test device 10 as illustrated in the block diagram, the electrical test device 10 can simultaneously measure current and voltage of the electrical system due to the application of current sourcing into the electrical system under test.

It should be noted that although each of the functional blocks is indicated as a separate block, componentry may be shared therebetween for facilitating any particular measurement of the electrical system. Furthermore, as can be seen, each of the functional blocks is connected to the processor 92 or microprocessor 40 which controls the operation of the electrical test device 10 during testing. It should also be noted that the dual continuity tester 118 functionality block shown in FIG. 1 may be used in conjunction with the current source provide by the probe when energized by the power supply 88. Such operation of the current source provided by the probe is similar to that which is disclosed in U.S. Pat. No. 5,367,250, issued to Whisenand (“the Whisenand reference”) and which is entitled “Electrical Tester With Electrical Energizable Test Probe,” herein incorporated by reference in its entirety. The operation of the dual continuity tester 118 of the electrical test device 10 in combination with its signal lamps 58 provides for an extremely convenient means for testing the functionality of multi-pole relays. More specifically, the dual continuity tester 118 is configured to allow testing of multiple contacts with the pressing of a single button of the electrical test device wherein the coil resistance of the relay may be easily measured. In addition, many other test configurations may be obtained.

Likewise, the current sourcing functionality shown in FIG. 1 is similar to that shown and disclosed in the Whisenand reference. The dual continuity tester 118, when coupled with the measurement functions of the electrical test device 10, enables testing of contact switches in relay devices. For example, in an electrical system having two relays, the dual continuity tester 118 provides for the capability to determine which one of the two relays is activated and/or which is deactivated. In this manner, the dual continuity tester 118 allows for checking of relays using either a pair of signal lamps 58. When testing relays or switches in this manner, the speaker 66 is preferably configured to be inoperative to avoid producing audible signals that may otherwise impede detection of noises that are indicative of a functioning switch. Both the signal lamp 58 and/or the audible device may be used to provide an indication as to the activated or deactivated state of the relays. Furthermore, the dual continuity tester 118 may be used to check the status and operability of multiple contacts such as in a multi-pole/multi-contact relay or switch.

Referring still to FIG. 1, the load impedance detector 120 functional block allows for measurement of the magnitude of a voltage drop such as when testing electrical junctions in an electrical circuit. The load impedance detector 120 functional block is useful in testing power feed circuits that may have loose or corroded connections. As will be described in greater detail below, when the probe element 50 is connected to the electrical system under test, the impedance of the electrical system may be tested and the electrical test device 10 may provide an indication, either audibly via the speaker 66 and/or visually via the display device 54 (i.e., the LCD 56) such as when a set point (i.e., a predetermined voltage level) is above a specified voltage limit.

The logic probe generator and detector 122 functional block comprises a circuit that creates a sequence for outputting into a device of the electrical system through the probe element 50. For example, a digital pulse train may be inputted into a device of the electrical system with the digital pulse train inserted into a terminal of a device under test in order to assess communication between components of the electrical system (e.g., between an odometer in communication with a control unit of a motor vehicle). The logic probe generator and detector 122 functionality also provides the electrical test device 10 with a capability to detect and/or measure signal levels as well as frequency. High and low logic levels may be generated as well as pulse trains at various frequencies.

The frequency and totalizer detection and/or measurement 124 functional block allows the electrical test device 10 to assess the rate of voltage or current fluctuation in the electrical system under test, and to accumulate occurrences of a particular state over time. Circuitry of the frequency and totalizer detection and/or measurement 124 block allow for processing of signal transition of a waveform in order to extract the frequency, revolutions per minute (RPM), duty cycle and number of pulses from a signal. The frequency aspect of the frequency and totalizer detection and/or measurement 124 functional block allows for determining the frequency or RPM or duty cycle component of the electrical system. The totalizer aspect of the frequency and totalizer detection and/or measurement 124 functional block accumulates pulses or cycles and allows the electrical test device 10 to detect and/or measure and check for intermittent output signals from the electrical system under test. The frequency and totalizer detection and/or measurement 124 functional block also provides a means for checking switches in an electrical system by providing a means for detecting and/or measuring the number of times that a contact within a switch bounces, for example, such as may occur in a relay switch.

The voltage detection and/or measurement 126 block allows for high-speed voltage detection and/or measurement 126 in the electrical system. The voltage detection and/or measurement 126 block represents the ability of the electrical test device 10 to sample and detect positive and negative peaks of a signal as well as detecting and/or measuring an average of the signals and displaying results of the signal readout on the display device 54. The voltage detection and/or measurement 126 block simplifies voltage drop tests, voltage transient tests and voltage fluctuation or ripple tests. The power output driver 128 with over current protection functional block provides a buffer stage or a transistor for the electrical test device 10 such that the power output driver 128 with over current protection regulates the amount of current that may be passed from the power supply 88 to the probe element 50 and ultimately into the electrical system under test. In addition, the power output driver may establish an appropriate drive impedance and protect the electrical test device 10 from damage due to automotive transients. The current detection and/or measurement 130 functional block allows for high-speed current detection and/or measurement 130 by the electrical test device 10 such that sampling and detection of current consumed in a load provided in the input signal which is passed into the electrical system. Such consumed current may be displayed on the display device 54.

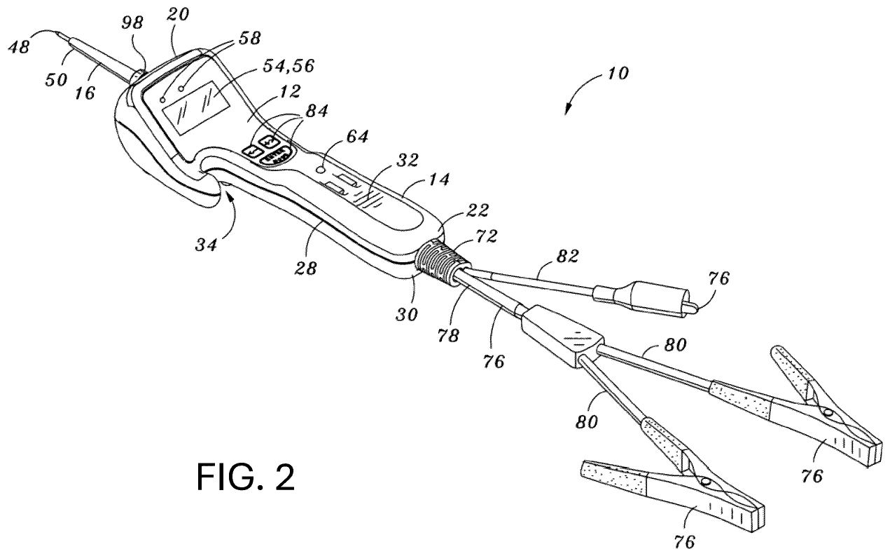

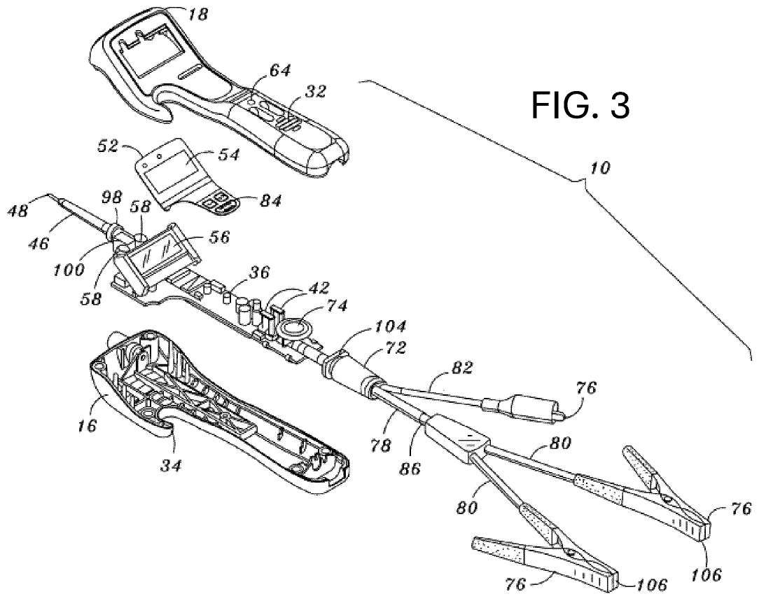

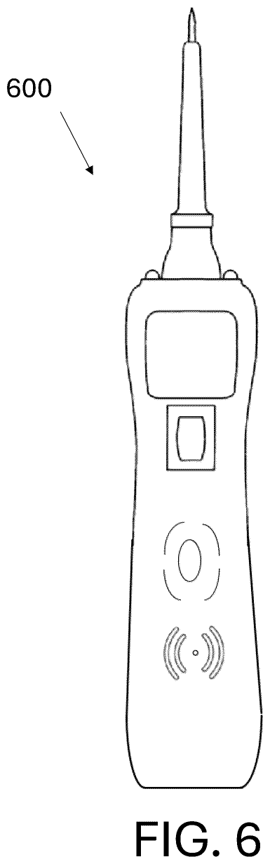

Referring now to FIG. 2-6, shown are embodiments of an electrical test device. Specifically, electrical test device 10 is schematically illustrated in FIG. 1 and electrical test device 600 is depicted by FIG. 6. As best shown in FIG. 2-3, the electrical test device 10 may include a housing 14 configured as a generally elongated, hollow, rectangular cross-sectionally shaped box. The housing 14 has a top end 20 and a bottom end 22. The top end 20 may be generally wider than a remaining portion of the housing 14 so that a display assembly 52 containing the display device 54 may be incorporated into the housing 14. The display device 54 may be supported with display supports 44 which may orient the display device 54 at a convenient angle for observation by an operator of the test device 10. The remaining portion of the housing 14 may have a narrower width to allow for single-hand operation of the test device 10.

Contained within the housing 14 is a circuit board assembly 36 comprising a circuit board 38 whereon a microprocessor 40 and display device 54 along with the power supply 88, microprocessor 40 reset control 94, speaker driver 68 and display driver 96 may be enclosed and interconnected. The housing 14 includes an upper shell 18 and a lower shell 16 which may be fastened to one another such as by mechanical fasteners. As can be seen in FIGS. 2 and 3, the housing 14 includes an upper wall 24 disposed with the upper shell 18 and a lower wall 26 disposed with the lower shell 16. In its assembled 64 state, the housing 14 includes opposing side walls 28 and opposing end walls 30. At the top end 20 of the housing 14 is an aperture formed therein and into which a probe jack 98 may be fitted. The probe element 50 is configured to be removably inserted into the probe jack 98. A probe overmold 46 may be provided to encase a major portion of the probe element 50.

At the bottom end 22 of the housing 14 is another aperture formed therein and through which a power cable 78 protrudes. The power cable 78 is configured with a pair of power leads 80, preferably one positive lead and one negative lead. In addition, a ground lead 82 may be also included in the power cable 78 extending out of the bottom end 22 of the housing 14. Both power leads 80 may be configured as insulated conductors as may be the ground lead. The cable 50 maybe encased in a cable sheathing 86 which passes through an annular shaped bushing 72 coaxially fitted within the aperture formed in the end wall 30 and which may prevent undue strain on the cable 50. The cable 50 includes a proximal end 104 which is disposed adjacent the housing 14 aperture and the strain relief bushing 72. The cable 50 also includes a distal end 106 having a pair of high power alligator clips 76 disposed on extreme ends of each one of the power leads 80.

As was earlier mentioned, the external power source 90 may be configured as a motor vehicle battery with the alligator clips 76 being configured to facilitate connection thereto. In this regard, the negative one of the power leads 80 may be provided in a black-colored alligator clip 76 while the positive one of the power leads 80 may be provided with a red-colored alligator clip 76. Disposed at an end of the ground lead 82 may also be an alligator clip 76 to facilitate connection to a ground source. As can be seen in FIG. 2, the upper and lower shells 16, 18 of the housing 14 are configured to provide a hang loop 34 extending out of one of the side wall 28. The hang loop 34 provides a mechanism by which the electrical test device 10 may be attached to or hung from fixed objects such as a cable or a hook.

As can be seen, the power cable 78 is electrically connected to the circuit board assembly 36. As was previously mentioned in the description of FIG. 1, the external power source 90 is connected via the power cable 78 to a power supply 88 which is integrated with the circuit board assembly 36 and which is ultimately connected to the probe element 50 extending out of the top end 20 of the housing 14. Included with the probe element 50 is a probe tip 48 on an extreme end thereof. Advantageously, the probe element 50 is configured to be removable from the electrical test device 10 via a probe jack 98 such that various electrical testing accessories may be plugged into the probe jack 98 for checking the electrical system under test.

Referring now to FIG. 5, shown is a front view of the electrical test device 10 and illustrating openings or apertures formed within the housing 14 through which illumination lamps 60 at least partially extend. The illumination lamps 60 may optionally be provided for illuminating an area adjacent to the test probe. Although four apertures and illumination lamps 60 are shown, any number may be provided. It is contemplated that the illumination lamp 60 or lamps may preferably be configured as light emitting diodes 64 (LEDs). Activation and deactivation of the illumination lamps 60 may be provided by means of the keypad 84 which is electrically connected to the processor 92 or microprocessor 40 located on the circuit board 38 and which may be disposed at a location adjacent to the display device 54.

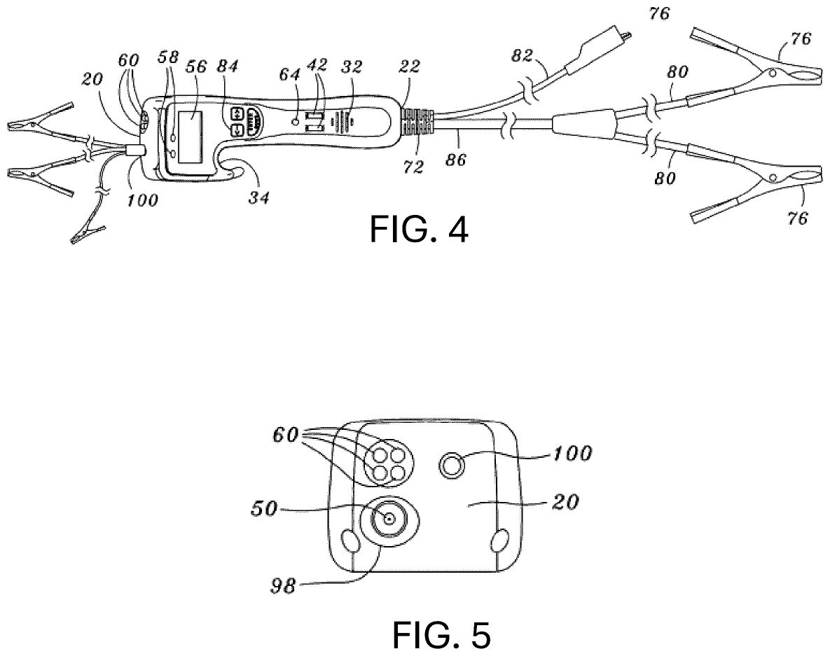

Also shown in FIG. 4-5 is an auxiliary jack 100 into which an auxiliary cable 102 may be inserted for facilitating continuity detection and/or measurements as was described above with regard to the dual continuity tester 118 functionality block. The auxiliary cable 102 has a proximal end 104 and a distal end 106 and comprises a pair of auxiliary test leads 108 and the auxiliary ground lead 110. The auxiliary test leads 108 comprise a first continuity test lead 112 and a second continuity test lead 114. In addition, the auxiliary cable 102 may include an auxiliary ground lead 110 for use as a continuity test common ground 116. The auxiliary jack 100 formed within the housing 14 is electrically connected to the processor 92 or microprocessor 40. As was previously mentioned, the auxiliary ground and test leads 110, 108 are adapted to be selectively insertable into the auxiliary jack 100 at the proximal end 104.

Referring now to FIG. 3, mounted with the housing 14 is the display device 54, which may be configured as a liquid crystal display 56 (LCD). In order to protect the display device 54 as well as the interior of the housing 14, a display overlay 12 may be included and is preferably disposed generally flush or level with an upper wall 24 of the housing 14. In addition, the display overlay 12 may extend along the upper shell 18 to form a protective barrier for the keypad 84 integrated into the electrical test device 10. As was earlier mentioned, the keypad 84 allows for manipulation of the processor 92 or microprocessor 40 for controlling functionality of the electrical test device 10. The keypad 84 may be comprised of any number of keys but preferably may include three (3) buttons for operation of the electrical test device 10. The three (3) buttons of the keypad 84 may be preferably configured to allow for selective switching between different detection and/or measurement modes of the electrical test device 10.

In addition, the keypad 84 may allow for the configuration of detecting and/or measuring and displaying various parameters of AC voltage and DC voltage detections and/or measurements, resistance of the electrical circuit, current flowing within the electrical circuit, the frequency of signals, etc. More specifically, the electrical test device 10 may be manipulated such that parameters detected and/or measurable by the electrical test device 10 include at least one of the following: circuit continuity, resistance, voltage, current, load impedance, and frequency, RPM and pulse counting. In addition, further detection and/or measurement modes may be facilitated through manipulation of the keypad 84. For example, frequency, RPM, duty cycle and totalizer detection and/or measurements may be provided upon an electrical circuit in a test. In addition, signal level and frequency may be detected and/or measured as well as testing of impedance.

Referring still to FIG. 3, shown included with the circuit board assembly 36 may be at least one fuse 42 and preferably a pair of fuses 42 which partially protrude through apertures formed in the housing 14 at the upper shell 18. The fuses 42 are incorporated into the electrical test device 10 as a safety precaution to prevent damage to the circuitry of the test device 10. Also included with the electrical test device 10 may be a circuit breaker 62 such as an electronic circuit breaker 62 which may also have configurable trip levels and a manual circuit breaker reset. Also shown incorporated into the circuit board assembly 36 of the electrical test device 10 is a piezo element 70 which is shown configured as a piezo disk 74 and which is disposed adjacent the bottom end 22 of the housing 14.

Speaker holes 32 are shown formed in the upper shell 18 of the housing 14 to allow for transmission of audible tones generated by the piezo disk 74 such as may occur during the variously configurable modes of operation of the electrical test device 10. Also included with the circuit board assembly 36 may be an additional lamp configured as an LED 64 and which may protrude through an aperture formed in the upper shell 18 of the housing 14 as shown in FIGS. 2 and 3. Such LED 64 may be connected to the processor 92 or microprocessor 40 and may allow for providing a means to indicate whether power is being applied to the electrical test device 10. Alternatively, or in addition to, the LED 64 protruding through the upper shell 18 of the housing 14 may also be configured as a power-good indicator and to be de-activated to alert the user of a blown fuse 42.

Regarding the operation of the electrical test device 10, as was earlier discussed, the electrical test device 10 is operative in either one of the passive mode or the active mode. The passive mode is defined by detections and/or measurements of the electrical system with no power being supplied thereto by the probe element 50. The active mode is defined by detection measurement of parameters of the electrical system during application of power such as from an external power source 90 through the probe element 50 and into the electrical system.

As was earlier discussed, the electrical test device 10 may be operated as a dual continuity tester 118 wherein the auxiliary cable 102 may be inserted into the auxiliary jack 100 at the top end 20 of the housing 14 as shown in FIG. 4. After insertion, the first continuity test lead 112 and second continuity test lead 114 as well as continuity test common ground 116 may be connected to the electrical system under test. In the active mode, wherein power is supplied to the electrical system under test, the continuity of a particular portion of the electrical system may be verified by using the auxiliary cable 102 comprising the first continuity test lead 112 and/or the second continuity test lead 114 in combination with the continuity test common ground 116.

As shown in FIG. 3, a pair of signal lamps 58 may be included with the test device 10 and may be positioned at the top end 20 of the housing 14 so as to protrude through apertures formed in the upper shell 18. The signal lamps 58 may be configured as LEDs 64 and, more specifically, may be configured as a yellow LED and a red LED. In addition, as was previously mentioned, the piezo element 70 may be used in combination with or may be exclusively during continuity testing. Importantly, the dual continuity tester 118 may use the current source provided by the external power source 90 for inputting current into the electrical system during continuity testing.

Load impedance detection functionality may be facilitated such that the magnitude of a voltage drop within an electrical system such as when testing electrical junctions in power feed circuits that may have loose or corroded connections. The electrical system under test may be detected and/or measured with differences there between being assessed and displayed on the display device 54. The logic probe generator and detection functional block, as was previously discussed, allows for testing for high logic, low logic and pulsing logic signals. The electrical test device 10 is configured to allow forcing of a signal into the electrical system under test with manipulation of multiple functions of the logic detection functionality such that an appropriate input signal may be injected into the electrical system under test.

The frequency and totalizer detection and/or measurement 124 functionality allows for detecting and/or measuring signals from the electrical system as well as providing the capability for entering a “divide ratio”, which may be equivalent to the number of cylinders of an engine within the motor vehicle being tested. In this manner, the electrical test device 10 may detect and/or measure the revolutionary speed at which a motor vehicle engine is operating. In addition, as was previously discussed, rates of voltage or current fluctuation may be detected and/or measured and signal transition components of a wave form may be analyzed to extract frequency, duty cycle and number of pulses. Regarding the voltage detection and/or measurement 126 functionality, the electrical test device 10 may detect and/or measure and display average voltage similar to that performed, detected, and/or measured by a standard voltmeter as well as detection and/or measurement and display of positive peak voltage and negative peak voltage. Importantly, the detection and/or measurement of negative peak voltage enhances the ability to analyze and detect and/or measure voltage of an alternator having a faulty diode.

The electrical test device 10 may be operated as a digital voltmeter capable of performing a voltage drop test and battery load testing as well as transient voltage testing. In addition, the combination of the power output drivers 128 with current detection and/or measurement 130 capability allows the electrical test device 10 of the present invention to detect and/or measure current and voltage simultaneously. The electrical test device 10 may be placed in the active mode and can be placed in a “latched” or permanent operation mode wherein a constant supply of power is provided through the conductive probe element 50 into the electrical system under test. However, the electrical test device 10 can be placed in a “momentary” power mode wherein power may be supplied on an as-requested basis due to manual manipulation of one of the buttons of the keypad 84.

The processor 92 or microprocessor 40 may be configured to cause periodic energization of the probe element 50 for powering the electrical system under test at predetermined intervals for testing an electro-mechanical device that is part of the electrical system under test. Examples of electro-mechanical devices that may be tested in this manner include, but are not limited to, relay switches, solenoids, motors and various other devices. Power may be provided to the electrical system under test on an automatic intermittent basis at predetermined intervals such as, for example, at one-second intervals. Advantageously, the ability to provide power in such varying modes allows for testing the proper operation of electro-mechanical devices such as relay switches as well as in tracing locations of such electro-mechanical devices. By connecting the electrical test device 10 to the external power source 90 and intermittently providing current into the electrical system through the probe element 50, a user may more easily track the location of a faulty relay switch by listening for a clicking sound as power is intermittently applied thereto. Such method for checking for faulty relay switches may be especially valuable in detecting a relay switch that may be hidden underneath carpeting, seating and/or plastic molding commonly found in automotive interiors.

The electrical test device 600 of FIG. 6 functions in the same manner as electrical test device 10 of FIGS. 2-5, but for conciseness, the description of the electrical test device 600 is not repeated herein. All functionality and components described with reference to FIGS. 1-5 equally apply to the electrical device 600.

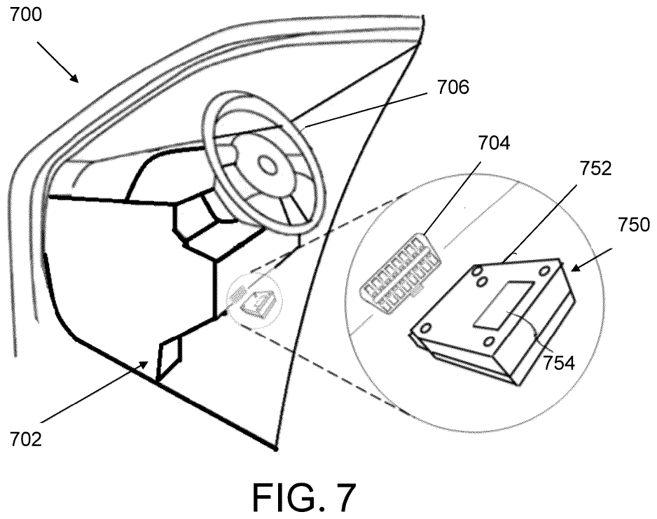

FIG. 7 depicts the front interior 702 on the driver's side of a vehicle 700 with a magnified view of a vehicle diagnostic port 704 and an example apparatus 750 for preserving memory settings and deriving parasitic draw of an electrical system of a vehicle 700, according to an implementation of the present disclosure. Many vehicles have an on-board diagnostics (OBD) port or a cigarette lighter socket/receptacle where devices can be connected to the electrical system of a vehicle. According to one embodiment, the vehicle diagnostic port 104 includes an OBD port, where any OBD tool (e.g., the apparatus 750) can be connected to the electrical system of the vehicle 700. The vehicle 700 may utilize an OBD system, which may essentially include a computer that is used to control and monitor important devices and components of the vehicle through a series of sensors. The OBD system may detect various abnormalities such as, for example, irregularities in the fuel/air mixture, problems with spark plugs, problems with the vehicle's catalytic converter, etc. The vehicle diagnostic port 704 may include a specific plug-in that allows the apparatus 750 to electrically connect to the OBD system to communicate and detect various abnormalities.

Initially, certain automobile manufacturers utilized a vehicle diagnostic port 704 commonly referred to as OBD-1 in accordance with certain standards that would give certain codes for various abnormalities that were not standardized across all vehicle manufacturers. Later, the United States implemented a nationwide standard that is commonly referred to as OBD-2, where all automobile manufacturers utilize a standardized port that can support the same type of scanner with standardized trouble codes. Devices that can be connected via an OBD-2 port can interface with the automobile's computer to retrieve real-time diagnostic data about the automobile. The OBD-2 standard has since been implemented by many nations across the world for standardization purposes. The OBD-2 standard utilizes a 16-pin data link connector (DLC). Specifically, in an automobile, the OBD-2 port of the automobile incorporates a female socket that is generally positioned near a steering wheel 706 of the vehicle 700.

According to various embodiments, the apparatus 750 disclosed herein is configured to connect to the electrical system of the vehicle 700 using OBD-1, OBD-2, or a cigarette lighter socket/receptacle, or various other connection ports. According to one embodiment, the apparatus 750 includes an interface that includes a 16-pin male connector configured to connect to the OBD-2 port of the vehicle 700. Further, the apparatus 750 may include a housing 752 within which various components (e.g., a power source, sensor(s), an analyzer, etc.) are housed. Additionally, the apparatus 750 may include a display 754 for displaying an output that is derived by the apparatus 750, where the output may include a current reading, a voltage reading, a parasitic drain reading, etc.

Within the housing 752, the apparatus 750 includes a power source (e.g., a battery) configured to energize the electrical system of the vehicle 700. According to various embodiments, the power source may include a rechargeable battery. The power source may facilitate preserving memory settings of the vehicle 700 while the primary battery source within the vehicle 700 is disconnected or removed. In particular, the power source may provide voltage and current via the interface so that the cable(s) of the electrical system can be disconnected from the vehicle's battery without losing user-specified settings of the electrical system of the vehicle 700. Advantageously, this functionality allows for disconnecting or replacing the main battery power source of the vehicle 700 while providing temporary power to, in part, preserve adaptations to fuel and spark controls of the engine control modules (ECMs). It is possible that the adaptations can be substantially differentiated from the default fuel and spark trims that the vehicle 700 may not even restart if it were to temporarily lose battery power. Thus, it is very important to preserve the memory settings of the vehicle when the primary battery or power source of the vehicle 700 is disconnected or removed. The apparatus 750 alleviates this concern by providing temporary power to the electrical system of the vehicle 700, which preserves the memory settings of the vehicle.

When a vehicle is operational, an alternator works together with the vehicle's primary power supply to supply power to the electrical components of the vehicle, including the vehicle's battery. In particular, when an alternator pulley is rotated, alternating current (AC) passes through a magnetic field and an electrical current is generated. Specifically, the alternator utilizes rotors that have magnets that move around iron plates of a stator to generate the alternating current in the stator windings. A rectifier can then be used to convert the alternating current to direct current (DC) and power both the electrical components and the vehicle's primary power source or battery. However, when the vehicle is turned off and not in operation, the alternator is not in use and any current draw is being pulled solely from the vehicle's primary power source or battery.

One issue that can lead to problems or complications with the primary power source or battery of the vehicle may stem from a continuous draw from the vehicle's primary power source or battery that is higher than the expected drain while the vehicle is turned off and not in operation. Most vehicles are expected to have a small current draw that is typically less than fifty milliamps (50 mA) when the vehicle is turned off and not in operation in order to maintain memory settings as described above. One reason for this is that various on-board systems turn off at different times and at different rates. In some vehicles, it may take several hours for some systems to fully shut off. Another current draw that exists in some vehicles when the vehicle is turned off and not in operation may include an anti-theft system. Current draw levels below 50 mA are insufficient to drain the vehicle's primary power source or battery. However, when the primary power source or battery is subject to higher levels of current draw when the vehicle is turned off and not in operation, this can unnecessarily cause the vehicle's primary power source or battery to prematurely drain over a relatively short period of time (e.g., over a few days or even overnight) and can shorten the lifespan of the vehicle's primary power source or battery. Battery drain that occurs when the vehicle is turned off and not in operation is commonly referred to as a “parasitic draw” and excessive parasitic draw can lead to parasitic power loss once the battery is sufficiently drained.

In order to detect and/or measure the parasitic draw levels being exerted on the battery, vehicle technicians often utilize an Ampere meter (i.e., ammeter) or a multimeter (i.e., a tool that possesses the capability of a voltmeter ammeter, and ohmmeter). A common existing method that utilizes the ammeter is to remove the minus (or plus) terminal cable from the vehicle's battery and then connect the ammeter in series between the minus (or plus) pole of the battery and the minus (or plus) terminal of the cable so that the ammeter can display the withdrawal current between the vehicle's battery and the vehicle's battery cable to detect and/or measure the current levels when the vehicle is turned off and not in operation. This step is followed by individually disconnecting one fuse at a time until the current value from the ammeter drops in order to identify the part of the electrical system that is exerting the parasitic draw. Once the part causing the parasitic draw is located, various other steps can be taken to determine exactly how to replace the part or otherwise resolve the issue. However, removing the minus (or plus) terminal cable from the vehicle's battery in order to utilize the ammeter creates various risks associated with losing memory settings of the vehicle if a backup power source to preserve the memory settings is not simultaneously being used when the battery cable is disconnected.

Because best practice requires vehicle technicians to utilize a backup battery (e.g., a “memory saver”) to preserve the memory settings, it would be advantageous if the device that provides the backup battery could also incorporate the capabilities of the ammeter to detect and/or measure the parasitic draw. This would eliminate the need for separate tools where one tool could perform the memory saver function and the other tool could detect and/or measure the current draw. However, unlike existing ammeter systems that detect parasitic draw by connecting the ammeter in series between the minus (or plus) pole of the vehicle's primary battery and the minus (or plus) terminal of the cable, the apparatus 750 detects and/or measures the current draw on the backup battery itself. Because the backup battery of the apparatus 750 is providing power to the vehicle, detection and/or measurement of the current being provided by the backup battery 750 would produce the same reading as if the ammeter were to be connected in series between the minus pole of the vehicle's primary battery and the minus (or plus) terminal of the cable. Thus, once the apparatus 750 is connected to the vehicle diagnostic port 704, the vehicle can disconnect one battery terminal and the apparatus 750 can be used to derive the parasitic draw of the electrical system of the vehicle 700.

In particular, the apparatus 750 may include an analyzer that is used to derive the parasitic draw, where the analyzer includes an ammeter capable of detecting current flow from a power source of the apparatus 750 to an electrical system of a vehicle 700 and/or a voltmeter for detecting and/or measuring voltage that is being transmitted from the power source to the electrical system of the vehicle. According to various embodiments, the apparatus 750 includes a display capable of displaying an output reading representing the derived parasitic draw and/or displaying a voltage reading of the measured voltage. According to one embodiment, the display is further capable of displaying a graphical representation of changes in the current flow and the measured voltage over a period of time.

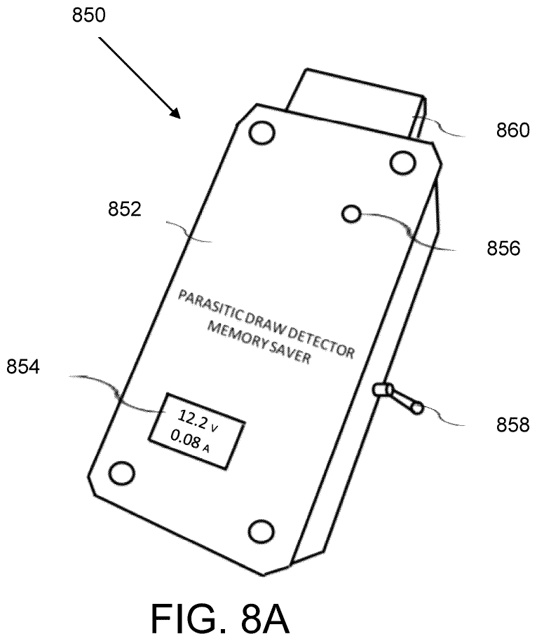

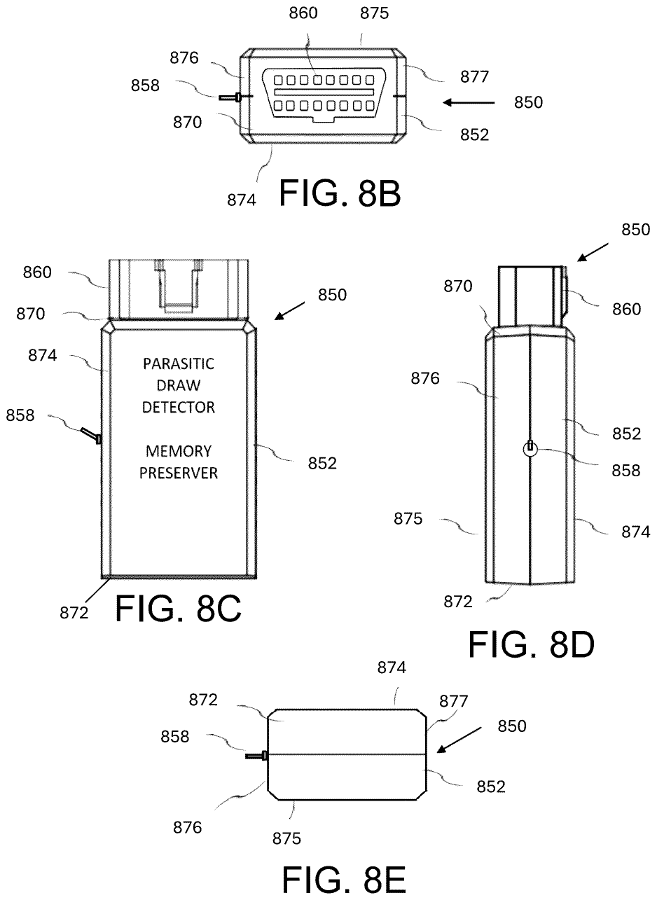

FIG. 8A illustrates a perspective view of an example apparatus 850 for preserving memory settings and deriving parasitic draw of an electrical system of a vehicle, according to an implementation of the present disclosure. The apparatus 850 may include a housing 852 that encloses a power source configured to energize the electrical system of a vehicle and encloses one or more sensors, and an analyzer. For instance, the apparatus 850 may include one or more sensors (e.g., resistor(s)), housed within the housing 852, that are coupled (e.g., connected in series) to the power source of the apparatus 850. The sensor(s) (e.g., resistor(s)) may be configured to detect current flow from the power source of the apparatus 850 that is flowing to the electrical system of the vehicle when the electrical system is disconnected from the vehicle's primary battery source. The sensor(s) (e.g., resistor(s)) may include, according to various embodiments, a moving coil meter or a moving iron meter that when coupled to the power source can detect current flow from the power source to the electrical system of the vehicle. In some embodiments, the sensor(s) may incorporate a small resistor that is placed in parallel with a galvanometer (e.g., an actuator) to shunt most of the current around the galvanometer and direct a pointer in response to electric current flow.

For instance, in one embodiment of a moving coil meter (e.g., a spindle), the sensor(s) (e.g., resistor(s)) may incorporate a set of moving coils with very low resistance and inductive reactance, which allows for low impedance. Further, the sensor(s) may be positioned within the field of fixed magnets set to oppose the current causing a centrally located armature attached to an indicator dial to move. Thus, when current flows through the coil, the coil generates a magnetic field that acts against the fixed magnets causing the coil to twist and the angular deflection is proportional to the current.

In moving iron meter embodiments, the ammeter may incorporate two vanes mounted within a coil, where one vane is fixed and the other vane is free to rotate. When current is applied through the coil, a magnetic field of the same polarity is induced into both vanes, which causes the free vane to be repelled by the fixed vane and the free vane rotates a distance that depends on the strength of the magnetic field, which represents the strength of the current.

As indicated above, the housing 852 may also enclose an analyzer that is electrically coupled to the power source and the sensor(s) (e.g., resistor(s)). According to various embodiments, the analyzer may analyze data in order to identify a pattern or relationship. For instance, the analyzer may analyze data obtained from the sensor(s) (e.g., resistor(s)) in order to quantify or otherwise detect and/or measure power flow, current flow, voltage, etc. According to various embodiments, the analyzer may include or incorporate a microcomputer, a microcontroller, an analog-to-digital converter (ADC), and/or a microprocessor. For instance, the analyzer may receive analog signals, such as analog voltage signals from current detection and/or measurement, and the ADC may convert the analog signals to a digital signal or digital data. The digital data may then be provided from the ADC to a processing device, such as a microprocessor, which can perform further analysis, calculations, or formatting of the data. In some example embodiments, the analyzer may incorporate various devices having a processing capability to add software algorithms to derive a parasitic draw of the electrical system of the vehicle. In some embodiments, the analyzer is in communication with a digital display 754 that allows a vehicle technician or other user to monitor the parasitic drain.

According to various embodiments, the analyzer may characterize various determinations, detections, measurements, and/or readings detected by the sensor(s) (e.g., resistor(s)). In one embodiment, the reading detected by the sensor(s) (e.g., resistor(s)) is a current flow reading, but various other readings may also be obtained including, but not limited to, impedance, wave forms, current drain, voltage, voltage drop, resistance, etc. and the analyzer may receive an output from the sensor(s) that is then analyzed. The output may include any representative signal of a detection and/or measurement of one or more parameters of the electrical system of the vehicle. The various components of the analyzer (e.g., processor, microprocessor, microcontroller, microcomputer, analog-to-digital converter, etc.) may utilize the output of the sensor(s) (e.g., resistor(s)) to generate an output signal to the digital display 854 that is representative of the output being detected and/or measured. The analyzer may incorporate a circuit board assembly comprising a circuit board upon which a microprocessor and the digital display 854 may be connected. Further, the power supply, microcontroller, display driver, and various other components may be interconnected. According to various embodiments, an audible device may be included with the apparatus 750 in order to provide an audible indication of certain operating parameters of the electrical system that are being detected and/or measured. For example, the audible device may include a piezo element that acts as a speaker to provide an audible output.

According to various embodiments, the analyzer may incorporate an analyzer system comprising various modules, where the modules perform different functionalities. In one example, the analyzer system may incorporate a battery module for deriving battery data, a current flow module for deriving current flow data, a voltage module for deriving voltage data, and the like. The analyzer may perform certain processing functionalities to detect various errors and provide various outputs for the errors. In particular, the analyzer may detect that the parasitic draw is elevated outside of an expected range, which triggers the analyzer to produce an output to alert a user that the parasitic draw is elevated. According to various embodiments, the analyzer may be configured to derive charge voltage, cranking voltage, charging voltage alternator ripple voltage, voltage of the vehicle's primary battery, and the like.

The apparatus 850 may incorporate various input-output (I/O) interfaces. According to one embodiment, the I/O interface may include a wireless connection such as a Bluetooth component or other wireless communication means for wirelessly connecting to an external computing device. In particular, the wireless communication means may be electrically coupled to the analyzer and the wireless communication means facilitates transmitting one or more readings from the analyzer across a network to an external computing device. The I/O interface may include the digital display 854, which may utilize, according to one example, a liquid crystal display (LCD), a light-emitting diode (LED) display, a thin-film transistor LCD, a quantum dot (QLED) display, an organic LED (OLED) display, etc. According to one embodiment, the I/O interface may incorporate a control panel for controlling functionality of the apparatus 850.

Also shown is an example interface 860 that would be electrically coupled to the power source of the apparatus 850. The interface may be configured to be electrically connected to the electrical system of the vehicle. According to various embodiments, the interface may include an auxiliary power outlet and may be configured to be electrically coupled to the electrical system of the vehicle via a direct current connection port. In another embodiment, the interface may include a sixteen-pin connection and is electrically coupled to the electrical system of the vehicle via a port (e.g., a diagnostic port). The apparatus 850 may also include a visual indication (e.g., a light) 856 indicating whether the apparatus is properly connected to the electrical system of the vehicle. The visual indication may be configured as a LED, and more specifically a color changing LED that utilizes, for example, a green color to indicate that the apparatus 850 is properly connected and supplying power to the electrical system of the vehicle or a red color to indicate that the apparatus 850 is not adequately connected.

The apparatus 850 may also include various switches including, for example, a double pole double throw (DPDT) switch 858 that has two inputs and four outputs and is operatively coupled to the analyzer. In particular, each input has two corresponding outputs connected thereto. The DPDT switch may be configured to regulate operation of various components of the apparatus 850. For instance, the DPDT switch 858 may include multiple positional settings, where each positional setting is configured to perform a different detection and/or measurement related to the electrical system of the vehicle. In one example embodiment, one positional setting may ensure that both the memory saver functionality to preserve the memory settings and the parasitic draw functionality to derive the parasitic draw. Another positional setting may turn off, according to one example, the parasitic draw functionality or another detection and/or measurement. Other variations of different positional settings and functionality regulations are also contemplated herein.

FIGS. 8B-8E illustrate various views of an example apparatus 850 for preserving memory settings and deriving parasitic draw of an electrical system of a vehicle, according to an implementation of the present disclosure. The apparatus 850 may include a housing 852 configured as a generally elongated, hollow rectangular shaped box. The housing 852 includes a front 870 and a back 872, where the front includes an interface 860 extending therefrom. As depicted, the interface 860 may incorporate a 16-pin DLC or some other interface for connecting to the electrical system of the vehicle. The housing 852 may also include a bottom 874, a top 875, a left side 876, and a right side 877. A DPDT switch 858 may protrude from the left side 876 of the apparatus 850. The top 875 and bottom 874 may be generally longer than the front 870 and back 872, and generally wider than the right side 877 and left side 876. According to one embodiment, the housing 852 may include or incorporate a top shell and a bottom shell connected along the left 876, right 877, front 870 and/or back 872 via mechanical fasteners such that when the top shell and bottom shell are aligned together they form the housing 852. Although not depicted, the back 872 may include, according to one embodiment, an aperture or port through which a charging cable may be removably connected.

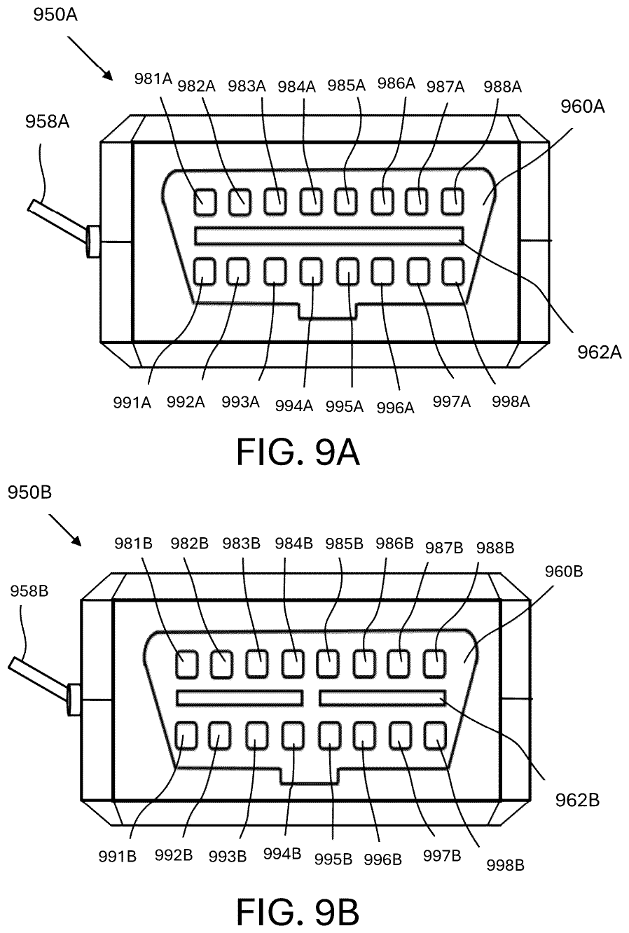

FIGS. 9A and 9B depict a front elevational view of example apparatuses 950A, 950B for preserving memory settings and deriving parasitic draw of an electrical system of a vehicle, according to an implementation of the present disclosure. In particular, apparatus 950A includes a J1962 Type A connection on the interface 960A and apparatus 950B includes a J1962 Type B connection on the interface 960B, which differ based on the shape of the alignment tabs 962A, 962B. Both the J1962 Type A and the J1962 Type B connection are OBD-II compliant connections. Each apparatus 950A, 950B has a respective DPDT switch 958A, 958B.

The J1962 Type A DLC standard indicates that the DLC shall be located in the passenger or driver's compartment in the area bounded by the driver's end of the instrument panel to 300 mm (˜1 ft.) beyond the vehicle centerline, attached to the instrument panel and easy to access from the driver's seat, with the preferred location being between the steering column and the vehicle centerline. The J1962 Type B DLC standard indicates that the DLC shall be located in the passenger or driver's compartment in the area bounded by the driver's end of the instrument panel, including the outer side and an imagined line 750 mm (˜2.5 ft.) beyond the vehicle centerline and attached to the instrument panel for easy access from the driver's seat or from the co-driver's seat or from the outside and mounted to facilitate mating and unmating. Various other OBD-II compliant connections may also include various other protocols such as, for example, J1850 PWM, J1850 VPW, ISO9141-2, ISO14230-4 (also known as Keyword Protocol 2000), ISO15765-4/SAE J2480. Other example interface embodiments, although not depicted, may include a cable and clip configured to fit within a power source receptacle or cigarette lighter receptacle of a vehicle.

The OBD-II standard has some pin locations within the 16-pin DLC that have standardized functionalities and that are required by all vehicle manufacturers. Other pins are left to the individual manufacturer's discretion. For the apparatus 950A (the J1962 Type A DLC) and apparatus 950B (the J1962 Type B DLC) each pin represents a different functionality. For instance, along the first row pins 981A and 981B can be specific to the manufacturer; pins 982A and 982B are bus positive lines; pins 983A and 983B have different functionalities based on the manufacturer (Ford Data Communications Link (DCL) or Chrysler Collision Detection (CCD)); pins 984A and 984B are the chassis ground pins; pins 985A and 985B are signal ground lines; pins 986A and 986B are the computer area network (CAN) high bus lines (which can carry either 2.5V or 3.75V depending on whether they are in idle mode or whether data bits are being transmitted); 987A and 987B are K-lines (bidirectional serial communication line using the K-line protocol); and 988A and 988B are left to the manufacturer's discretion. Further, along the second row pins 991A and 991B, pins 993A and 993B (Ford Data Communications Link (DCL) or Chrysler Collision Detection (CCD)), pins 994A and 994B, and 995A and 995B are left to the manufacturer's discretion; pins 992A and 992B are bus negative lines; pins 996A and 996B are CAN low bus lines (which can carry either 2.5V or 1.25V depending on whether they are in idle mode or whether data bits are being transmitted), pins 997A and 997B are L-lines (unidirectional line used only during initialization to convey address information from a diagnostic tester to the vehicle electronic control units (ECUs); and pins 998A and 998B are battery positive lines.

According to one embodiment, the apparatuses 950A and 950B may provide, when connected via the interface 960A, 960B to the electrical system of the vehicle, 12V DC power via pins 998A or 998B to supply power to the electrical system of the vehicle and will utilize the chassis ground pins 984A and 984B.

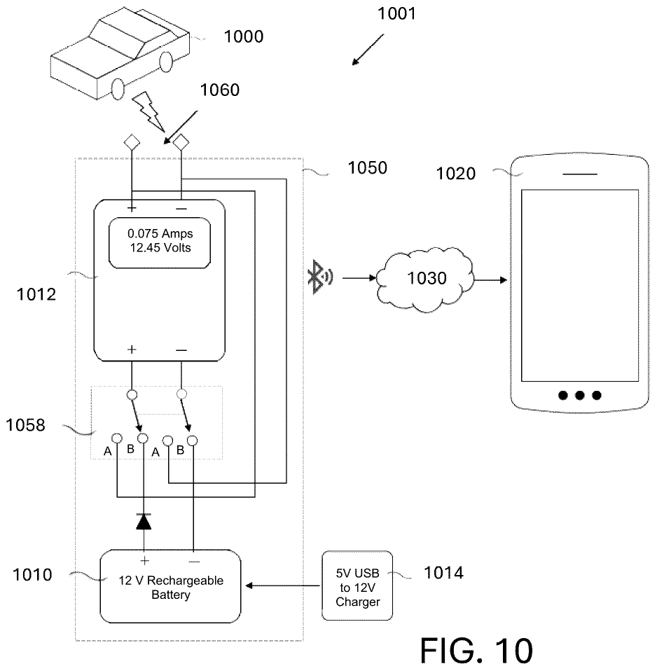

FIG. 10 depicts an example system 1001 for preserving memory settings and deriving parasitic draw of an electrical system of a vehicle 1000, according to an implementation of the present disclosure. The system 1001 includes an apparatus 1050 that includes a power source 1010 (e.g., a 12V rechargeable battery) that is configured to energize the electrical system of the vehicle 1000. Additionally, the apparatus 1050 includes an analyzer 1012 that is electrically coupled to the power source and also electrically coupled to one or more sensors (e.g., resistor(s)) configured to detect current flow from the power source 1010 to the electrical system of the vehicle 1000. According to one embodiment, the analyzer 1012 comprises the sensor(s) (e.g., resistor(s)) such that the one or more sensors are internal to the analyzer 1012 component. The analyzer is configured to derive a parasitic draw of the electrical system of the vehicle 1000 based on current flow that is detected by the sensor(s) (e.g., resistor(s)). The apparatus 1050 also includes an interface 1060 electrically coupled to the power source 1010 and that is configured to electrically connect to the electrical system of the vehicle 1000.

The apparatus 1050 is configured to perform a method based on the apparatus 1050 being electrically coupled, via the interface 1060 to the electrical system of the vehicle 1000 while one or more cables (e.g., the minus terminal cable and/or plus terminal cable) of the electrical system are disconnected from a vehicle battery (e.g., the respective minus pole and/or plus pole). The method includes preserving, by providing power via the power source 1010, memory settings of the electrical system of the vehicle 1000 and deriving, via the analyzer 1012, the parasitic draw of the electrical system of the vehicle 1000.

According to one embodiment, the apparatus 1050 may include a USB port (e.g., a USB-C port), a wired cord, or other electrical connection means for charging the power source 1010 (e.g., due to the power source 1010 being rechargeable). For instance, an external power supply 1014 may be used to charge the power source 1010. The power supply 1014 may include, in one particular example, a 5V USB that is used to charge the 12V power source 1010. According to various embodiments, the apparatus 1050 may be electrically connected to the power supply 1014 during operation (i.e., connected to the electrical system of the vehicle 1000) or the power source 1010 may be charged when not in operation. According to various embodiments, the power supply 1014 may connect (via a port) or otherwise be incorporated within the housing of the apparatus 1050. According to various embodiments, the power source 1010 may have a minimum energy charge capacity of at least 500 milliampere hours (500 mAh), more particularly at least 1,000 mAh, and more preferably at least 1,500 mAh. Further, according to one embodiment, the maximum current output of the power source 1010 may be 5 amperes (5 A). According to one embodiment, the power source 1010 may include a battery monitor that provides a state of charge of the power source 1010.

According to various embodiments, the power source 1010 may include various protection mechanisms preventing the power source 1010 from providing power to the electrical system of the vehicle 1000 while the vehicle 1000 is in operation. For instance, if the apparatus 1050 is connected to the vehicle 1000 while the vehicle 1000 is operational, this may cause an overcharging condition. Thus, various conditions may need to be satisfied in order for the power source 1010 to transmit power to the electrical system of the vehicle 1000.

Although not depicted, the apparatus 1050 may also include an I/O interface (e.g., a display), according to various embodiments, that is configured to display a voltage reading, current reading, and/or parasitic draw. For instance, the I/O interface may display a numerical value digitally represented via the display. Accordingly, the method performed by the apparatus 1050 of the system 1001 may also include displaying, via a display of the apparatus 1050, one or more readings derived from the analyzer, where the one or more readings are selected from a voltage reading, current reading, and/or parasitic draw. According to one embodiment, the apparatus 1050 may include a selectable display mode that displays, via the display, a graph representing current readings and/or voltage readings over a period of time, which will thereby allow a vehicle technician to monitor the current readings and/or voltage readings over extended periods of time.

According to one embodiment, the I/O interface may incorporate and/or be operatively connected to a drain monitor that displays battery voltage, power consumption, estimated remaining runtime, current consumption, battery temperature, and/or various other detections and/or measurements. According to various embodiments, the drain monitor may include a shunt-based or voltage-based monitor.

Additionally or alternatively, according to various embodiments, the apparatus 1050 may include a communication means for communicating with an external computing device 1020 (e.g., a laptop, desktop computer, mobile computing device (i.e., smartphone), portable digital assistant, pager, virtual assistance device such as a smart speaker or other smart home device, or any combination of the aforementioned, or other portable device with processing and communication capabilities). The apparatus 1050 may utilize, according to one embodiment, a wired or wireless communication means. For instance, the apparatus 1050 may include a radio-frequency transceiver to communicate via Bluetooth with the external computing device 1020. In various embodiments, the apparatus 1050 may include a Bluetooth communication means (e.g., a Class 2 Bluetooth transceiver), a Wi-Fi communication means, a near-field communication means, and/or other transceivers. Alternatively, the apparatus may connect via a connection port for wired connections via USB, Ethernet, and/or other physically connected modes of data transfer.

In some embodiments, the apparatus 1050 may include a transmitter, receiver, transceiver, etc. and/or other communication interface (e.g., an antenna) that provides signals to and/or receives signals from the respective transmitter or receiver of the external computing device 1020. According to one embodiment, the apparatus 1050 may be configured to operate in accordance with various cellular communication protocols (e.g., second-generation (2G) wireless communication protocols, third-generation (3G) wireless communication protocols, fourth-generation (4G) wireless communication protocols, fifth-generation (5G) wireless communication protocols, and/or the like). In other embodiments, the apparatus 1050 may be configured to operate in accordance with non-cellular communication mechanisms, such as via a wireless local area network (WLAN) or other communication data network.

According to various embodiments, the apparatus 1050 may communicate via a network 1030, which is singly depicted for illustrative convenience, but may include more than one network without departing from the scope of these descriptions. In some embodiments, the network 1030 may be or provide one or more cloud-based services or operations. The network 1030 may be or include an enterprise or secured network, or may be implemented, at least in part, through one or more connections to the Internet. A portion of the network 1030 may be a virtual private network (VPN) or an Intranet. The network 1030 can include wired and wireless links, including, as non-limiting examples, 802.11a/b/g/n/ac, 802.20, WiMAX, LTE, and/or any other wireless link. The network 1030 may also include one or more local area networks (LANs), radio access networks (RANs), metropolitan area networks (MANs), wide area networks (WANs), personal area networks (PANs), WLANs, campus area network (CAN), metropolitan area network (MAN), storage-area network (SAN), all or a portion of the internet and/or any other communication system or systems at one or more locations. The network 1030 may include any internal or external network, networks, sub-network, and combinations of such operable to implement communications between various computing components within and beyond the illustrated system 1001.

According to one embodiment, the method further includes transmitting, via a wireless network 1030 and by the wireless communication means (e.g., a transceiver), data indicating the derived parasitic draw to the external computing device 1020. Additionally or alternatively, the voltage measurement and/or current flow measurement may also be transmitted to the external computing device 1020. According to one embodiment, the wireless communication means utilizes short-range radio waves (e.g., Bluetooth technology). In one example, the parasitic draw, voltage measurement, and/or current flow measurement may be communicated to a vehicle technician via a mobile application accessible via the external computing device 1020. Advantageously, the wireless communication means may facilitate obtaining a more accurate reading of the parasitic draw. For instance, if the doors of the vehicle 1000 are open and various lights (e.g., dome lights, headlamps, etc.) may be turned on, and these additional accessories can affect the parasitic draw reading. Thus, by enabling a vehicle technician or other user to connect the apparatus 1050, close the doors, and step away from the vehicle 1000 while being able to view the parasitic draw via the external computing device 1020, the parasitic draw reading may be more accurate.

According to various embodiments, the data may only be transmitted based on the parasitic draw being outside of an acceptable measurement range. For instance, if the parasitic draw is less than or equal to 50 mA, the data may not be transmitted to the external computing device 1020, whereas if the analyzer 1012 derives that the parasitic draw is above 50 mA then the apparatus 1050 transmits the data to the external computing device 1020 indicating that the parasitic draw is above the acceptable range. According to one embodiment, the transmission may take the form of an alert (e.g., visual alert, auditory alert, etc.). For instance, according to one embodiment, the alert may be a notification provided via a mobile application accessible via the external computing device 1020. In another embodiment, the alert may take the form of an auditory alarm (provided via the external computing device 1020 and/or the apparatus 1050). According to various embodiments, different types of alerts may be different based on the detected and/or measured parasitic draw. For instance, various threshold values (e.g., 25 mA, 50 mA, 100 mA) of parasitic draw may trigger different alerts and/or alert formats.

According to one embodiment, data may be stored, via a storage device (e.g., random access memory (RAM), read-only memory (ROM), volatile memory such as a cache area for temporary storage of data, non-volatile memory that is embedded and/or removable such as electrically erasable programmable read-only memory (EEPROM), flash memory, or the like).

The interface 1060 may include a vehicle connection to the OBD diagnostic port (DLC), a cigarette lighter socket/receptacle, or various other connection ports of the vehicle 1000. For instance, the negative terminal of the interface 1060 may be connected via a chassis ground pin and the positive terminal of the interface 1060 may be connected via a battery positive line pin to the female socket of the vehicle 1000.

According to one embodiment, the analyzer 1012 may perform multiple functions including monitoring voltage and/or current. For instance, according to one embodiment, the sensor(s) (e.g., resistor(s)) may detect voltage drop across a resistor (that is connected in series with the power source 1010), and that voltage drop is then converted by the analyzer 1012 into a current value using Ohm's law, thereby deriving current flow. According to one embodiment, the analyzer 512 includes an ammeter and/or a voltmeter. The ammeter may include, for example, at least a 0.001 A resolution with the capacity to detect and/or measure between 0 A-10 A. Further, the voltmeter may include, for example, at least a 0.01V resolution with a capacity to detect and/or measure between 0V-30V. Depending on the magnitude of the parasitic draw derived by the analyzer 1012 that is above the acceptable level (50 mA), one or more processors of the apparatus 1050 or the external computing device 1020 may identify one or more likely causes of the increased parasitic draw. For instance, if the draw is between 75 mA and 100 mA the analyzer 1012 may be configured to determine likely reasons for the increased parasitic draw. In some embodiments in which the parasitic draw reading is transmitted to a mobile application accessible via the external computing device 1020, one or more videos and/or links may be displayed via the external computing device 1020 instructing the vehicle technician about possible techniques that may be used (e.g., determining the voltage drop across certain fuses to see which fuses are active) in order to identify the cause of the parasitic draw that would be outside of the acceptable range.

The apparatus 1050 may also include an internal/external selector switch, depicted as DPDT switch 1058. According to one embodiment, the DPDT switch 1058 may include a first position that enables the analyzer 1012 to detect and/or measure voltage from the electrical system of the vehicle 1000, and a second position that enables the analyzer 1012 to detect and/or measure voltage and current from the power source 1010 to the electrical system of the vehicle 1000. According to one embodiment, the power source 1010 is electrically coupled to the DPDT switch 1058 via a one-way diode, and the DPDT switch 1058 is electrically coupled to the analyzer 1012.

The apparatus 1050 may continue to preserve memory settings and derive parasitic draw of an electrical system of a vehicle 1000 for as long as the power source 1010 continues to provide power or until the primary battery of the vehicle 1000 is reconnected. For instance, once the apparatus 1050 detects that the vehicle's battery is reconnected the apparatus may detect that the battery is connected and cut off power to the electrical system of the vehicle 1000 so that the power source 1010 is no longer providing power to the electrical system and is not used to charge the vehicle's battery.

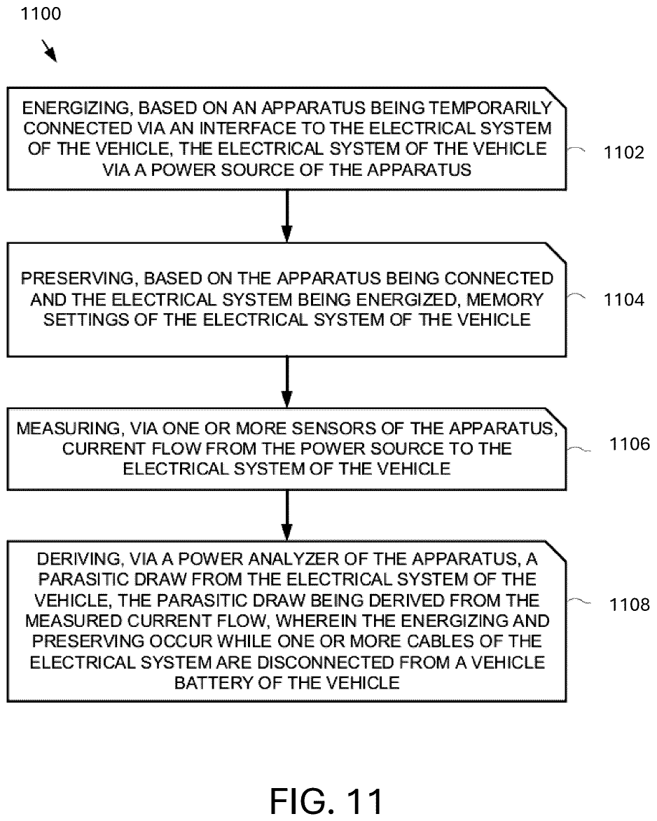

FIG. 11 depicts a block diagram of an example method 1100 for preserving memory settings and deriving parasitic draw of an electrical system of a vehicle, according to an implementation of the present disclosure. At block 1102, the method 1100 includes energizing, based on an apparatus being temporarily connected via an interface to the electrical system of the vehicle, the electrical system of the vehicle via a power source of the apparatus. At block 1104, based on the apparatus being connected and the electrical system being energized, memory settings of the electrical system of the vehicle are preserved. At block 1106, the method 1100 includes detecting and/or measuring, via one or more sensors of the apparatus, current flow from the power source of the apparatus to the electrical system of the vehicle. According to various embodiments, the analyzer includes an ammeter and/or a voltmeter.

At block 1108, the method 1100 includes deriving, via an analyzer of the apparatus, a parasitic draw from the electrical system of the vehicle, where the parasitic draw is derived from the detected current flow. In particular, the processes described by blocks 1102 and block 1104 occur while one or more cables of the electrical system are disconnected from a vehicle battery of the vehicle.

According to one embodiment, the method 1100 further includes transmitting, via a wireless network and by a wireless communication means of the apparatus, the derived parasitic draw to an external computing device. In one embodiment, based on the analyzer including a voltmeter, the method includes detecting voltage transmitted from the power source to the electrical system of the vehicle.

Disclosed herein are electrical testing devices, systems, and methods that have advantages over prior art devices, systems, and methods for identifying amperate. For example, the disclosed testing device has uniquely designed conductive probe elements (i.e., probes, leads, tips, etc.), which are cross-functional for different types of fuses. For instance, the conductive probe elements are designed to work effectively with standard fuses, mini fuses, maxi fuses, micro fuses, JCASE™ cartridge style fuses, and glass fuses. Many types of existing electrical testing systems utilize interchangeable leads for different types of fuses, which can lead to lost or misplaced leads or lead attachments. Further, switching out the interchangeable leads can lead to inefficiencies that would need the attachments to be switched out for each of the different types of fuses. In addition, the disclosed electrical testing devices, systems, and methods do not require a use to use two hands to hold each of the separate probes in order to contact the terminals of the fuse. This can be particularly burdensome in hard to access fuse boxes. Advantageously, the disclosed electrical testing device is easier to use, more efficient for vehicle technicians, and less likely to have lost or misplaced leads when they get disconnected from the electrical testing device. Accordingly, the clamping nature of the conductive probe elements provide an ergonomic, efficient, cross-functional, and fully integrated approach to facilitate electrical measurements.

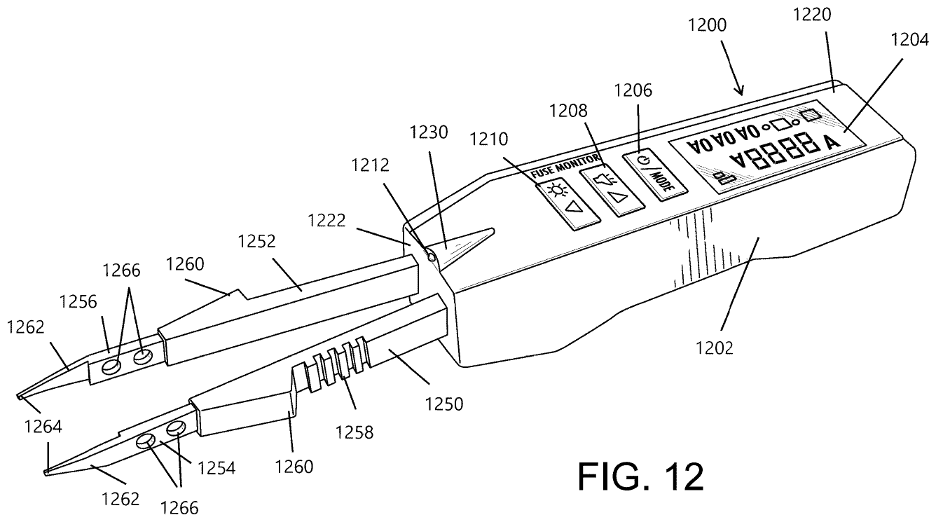

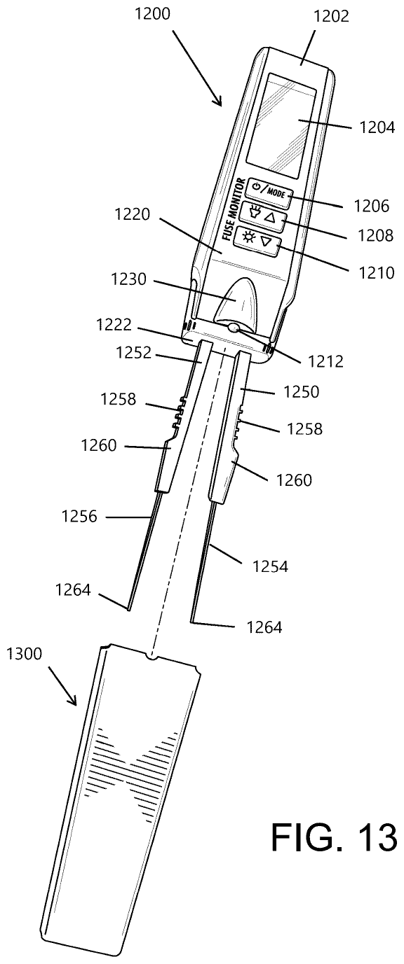

FIGS. 12-13 are perspective views of an electrical testing device 1200, in accordance with an embodiment of the present invention. The electrical testing device 1200, includes a housing 1202 having a communication interface that includes a display screen 1204 on the front face 1220 thereof. The face of the housing 1202 also includes a plurality of inputs 1206, 1208, 1210. As depicted, the inputs 1206, 1208, 1210 are selectable buttons, but in some embodiments, inputs may be incorporated into the screen itself (i.e., a touchscreen) or the inputs may include dials, knobs, sliders, switches, etc. In one embodiment, a first input 1206 is for selecting a mode associated with the electrical element for which a detection and/or measurement is being performed. In some instances, the first input 1206 may also double as an on/off switch such that holding the button for a prolonged period of time may be used to turn off the electrical testing device 1200 (including the backlight of the display screen 1204) or selecting the first input 1206 may initially turn on the device and illuminate the backlight of the display screen 1204. In some embodiments, the electrical testing device 1200 may automatically turn off after a predefined period of non-use. A second input 1208 is also located on the face 1220, where the second input 1208 is for turning on or off a light emitting diode (LED) 1212. A third input 1210 is also located on the face 1220, where the third input 1210 is for adjusting the brightness of the backlight of the display screen 1204.

As shown in FIG. 13, the electrical testing device 1200 is also configured to be at least partially housed within a sleeve 1300. For example, the sleeve 1300 may be configured to cover a first conductive probe element 1350 and a second conductive probe element 1352.

The electrical testing device 1200 also includes a first conductive probe element 1250 and a second conductive probe element 1252 that together form a pair of conductive probe elements 1250, 1252. The pair of conductive probe elements 1250, 1252 may extend outward from a bottom 1222 of the housing 1202. The LED 1212 is useful as it is directed toward the pair of conductive probe elements 1250, 1252 to illuminate the area that the pair of conductive probe elements 1250, 1252 would be contacting. This can be advantageous in dark areas where the fuse box may be located. Specifically, the LED 1212 may be positioned on the face 1220 of the housing 1202 and pointed in the direction of the bottom 1222 and the pair of conductive probe elements 1250, 1252. In order to provide the needed visibility, the face 1220 may include an outward projection or rise 1230 in the surface of the face 1220. In order to still provide a generally flat front face 1220 even with the surface rise associated with the LED 1212, the bottom portion of the front face 1220 may be sloped down and back away from the front face 1220 so that the rise 1230 associated with the LED 1212 protrudes outward from the face 1220 generally at a same amount as the remaining portion of the front face 1220.

The pair of conductive probe elements 1250, 1252 may include a soft material that encases much of a length of the pair of conductive probe elements 1250, 1252 starting proximate the bottom 1222 and extending outward towards the conductive tips 1254, 1256 of each of the respective conductive probe elements 1250, 1252. The soft material on each conductive probe element 1250, 1252 may include ridges 1258 for enhancing a person's grip. Further, the soft material may include outward facing protrusions 1260 that provide an ergonomically designed resting position for the user's fingers. The conductive tips 1254, 1256 may be a metallic material and may each have a tapered end 1262 that forms a point 1264, which allows for a precise contact surface for contacting terminals of an electrical element such as a fuse. Advantageously, the conductive tips 1254, 1256 may initially be wide before tapering to the point 1264, which provides more stability than a narrow wire. The width of the conductive tips 1254, 1256 would be less likely to bend or break during use when compared to a narrow wire. In some embodiments, the conductive tips 1254, 1256 include apertures 1266.

The electrical testing device 1200 may incorporate various input-output (I/O) interfaces. According to one embodiment, the I/O interface may include a wireless connection such as a Bluetooth component or other wireless communication means for wirelessly connecting to an external computing device (e.g., a laptop, desktop computer, mobile computing device (i.e., smartphone), portable digital assistant, pager, virtual assistance device such as a smart speaker or other smart home device, or any combination of the aforementioned, or other portable device with processing and communication capabilities). In particular, the wireless communication means may be electrically coupled to the analyzer and the wireless communication means facilitates transmitting one or more readings from the analyzer across a network to an external computing device. The I/O interface may include the display screen, which may utilize, according to one example, a liquid crystal display (LCD), a light-emitting diode (LED) display, a thin-film transistor LCD, a quantum dot (QLED) display, an organic LED (OLED) display, etc. According to one embodiment, the I/O interface may incorporate a control panel for controlling functionality of the electrical testing device 1200.

The display screen 1204 is configured to, and is capable of, displaying an output (e.g., amperage of the electrical element, such as a fuse, which is being tested) that is derived by a processor that is internal to the housing 1202. According to various embodiments, the processor may be associated with an analyzer and may be part of a microcomputer, a microcontroller, an analog-to-digital converter (ADC), and/or a microprocessor. The analyzer may analyze data in order to identify a pattern or relationship. For instance, the analyzer may analyze data obtained from the sensor(s) (e.g., resistor(s)) in order to calculate or otherwise determine amperage.

Specifically, when pair of conductive probe elements 1250, 1252 come into contact with respective terminals of the electrical element, the sensor(s) may collect data of the voltage drop across an in-circuit electrical path passing through the electrical element. The processor that is communicatively coupled to the sensor(s) may access the impedance data of the electrical element identified by the user and calculate, using Ohm's law (i.e., V=IR, where V=voltage, I=current, and Z=impedance) what the amperage (i.e., current) is that is passing through the electrical element. In particular, the analyzer may receive analog signals, such as analog voltage signals/determination of the voltage drop, and the analog-to-digital converter (ADC) may convert the analog signals to a digital signal or digital data. The digital data may then be provided from the ADC to the processor, which can perform further analysis, calculations, or formatting of the data.

The various components of the analyzer (e.g., processor, microprocessor, microcontroller, microcomputer, analog-to-digital converter, etc.) may utilize the output of the sensor(s) (e.g., resistor(s)) to generate an output signal to the display screen 1204 that is representative of the output being detected and/or measured. The analyzer may incorporate a circuit board assembly comprising a circuit board upon which a microprocessor and the display screen 1204 may be connected. In some example embodiments, the analyzer may incorporate a processor that uses software algorithms to derive various information indicative of a parasitic draw of the electrical system of the vehicle from the fuse. In some embodiments, the analyzer is in communication with the display screen 1204 that displays the amperage that has been derived from the voltage drop and the impedance of the electrical element selected.

According to one embodiment, the analyzer includes an ammeter and/or a voltmeter. The ammeter may include, for example, at least a 0.001 A resolution with the capacity to detect and/or measure between 0 A-100 A depending upon the type of fuse. Further, the voltmeter may include, for example, at least a 0.1 mV resolution with a capacity to detect and/or measure between 0 mV-10 mV.

In addition to a processor, the housing 1202 includes therein a power source (e.g., a battery) configured to energize the electrical testing device 1200. According to various embodiments, the power source may include a rechargeable battery. Further, the power supply, microcontroller, display driver, and various other components may be interconnected within the housing 1202.

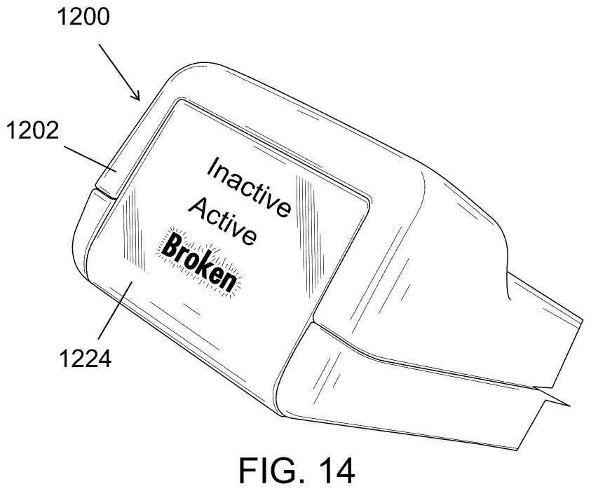

According to various embodiments, the analyzer may incorporate an analyzer system comprising various modules, where the modules perform different functionalities. In one example, the analyzer system may incorporate a voltage module for deriving voltage data. The analyzer may perform certain processing functionalities to detect various errors and provide various outputs for the errors. In particular, the analyzer may detect the status of the electrical element as being “Inactive,” which is indicative that there is no current going through the fuse, “Active,” which is indicative that there is current going through the fuse, and “Broken,” which is indicative that the fuse is broken. As depicted by FIG. 14, which is a top view of the electrical testing device of FIGS. 12-13, one or more indicator lights located on the top 1224 of the electrical testing device 1200 may provide a visual indication of a status (i.e., “Inactive,” “Active,” and “Broken”) of the electrical element. The one or more indicator lights may be configured as a LED, and more specifically a color changing LED that utilizes, for example, a green color to indicate that the status is “Inactive,” white/yellow to indicate that the status is “Active,” and red to indicate that the status is “Broken.”

Internal resistance of an electrical element causes resistance of the flow of charges going through the electrical element, where the resistance leads to a change in voltage (i.e., voltage drop) between two ends of the electrical element. Thus, the voltage drop is the difference in voltage of two terminals on the electrical element. By connecting a resistor in parallel with the electrical element, the voltage drop may be identified. For instance, the housing 102 may include one or more sensors (e.g., resistor(s)) that are coupled (e.g., connected in parallel) to the terminals of the electrical element.

The data storage location may store impedance data for many electrical elements, such as fuses, where the impedance data indicates the impedance of each electrical element. According to one embodiment, data may be stored, via a data storage location (e.g., random access memory (RAM), read-only memory (ROM), volatile memory such as a cache area for temporary storage of data, non-volatile memory that is embedded and/or removable such as electrically erasable programmable read-only memory (EEPROM), flash memory, or the like).

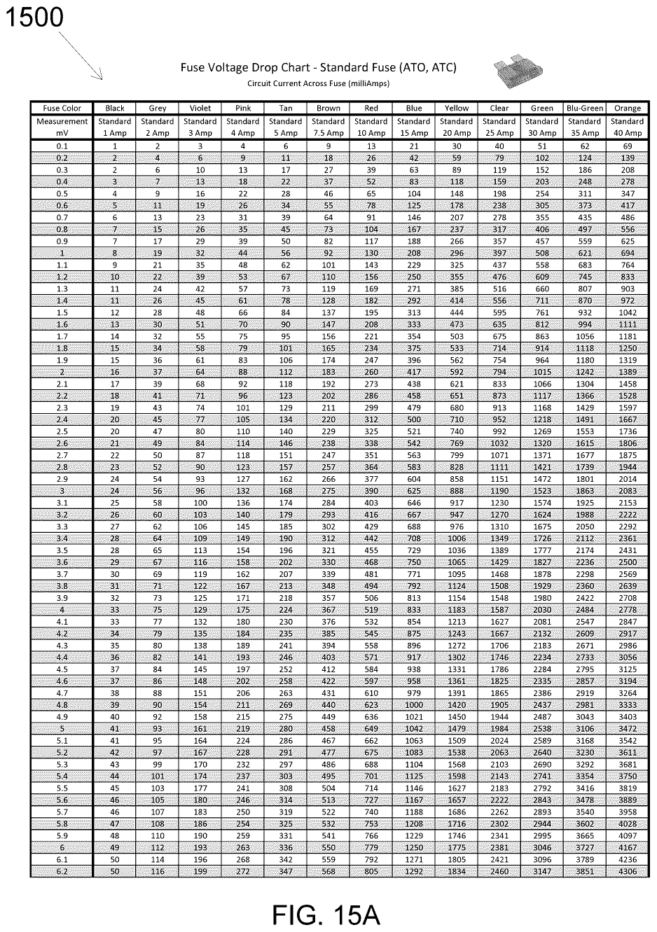

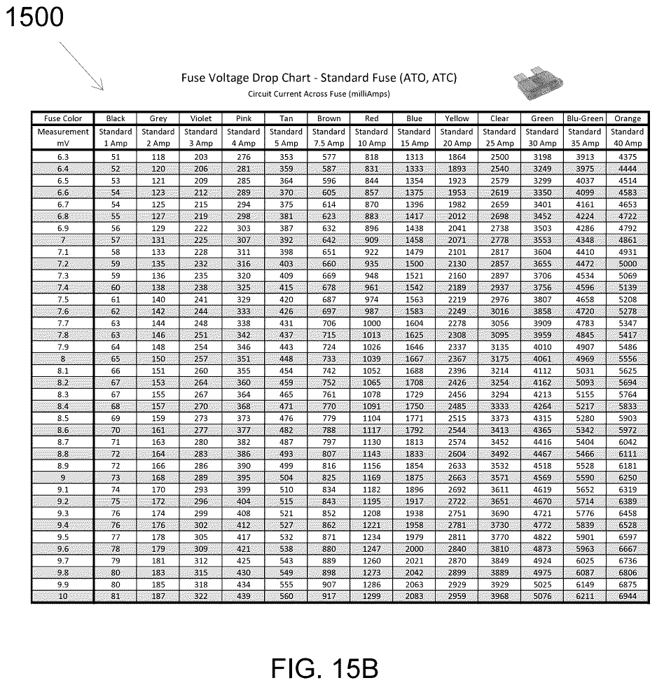

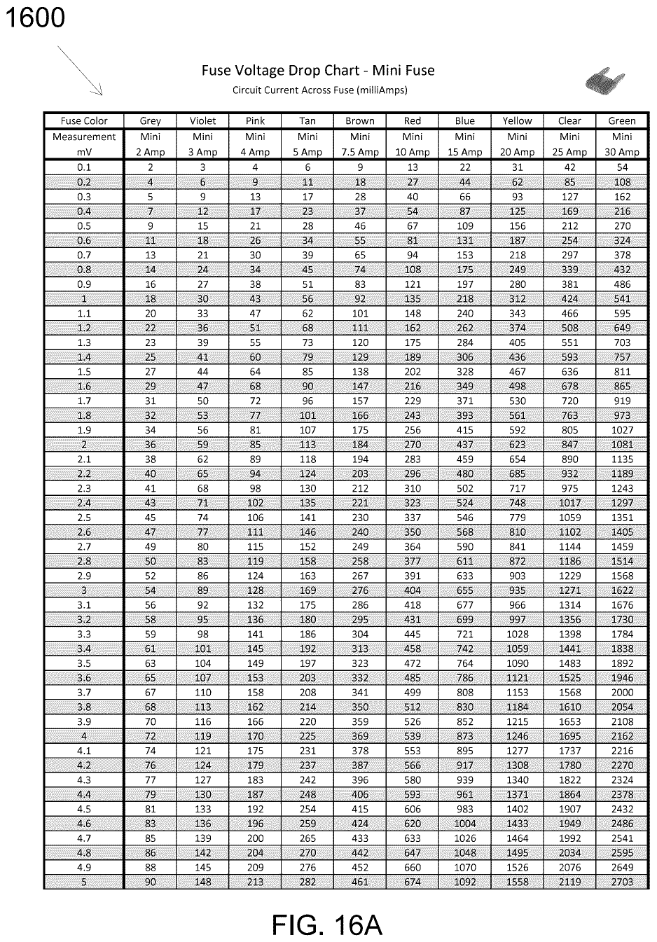

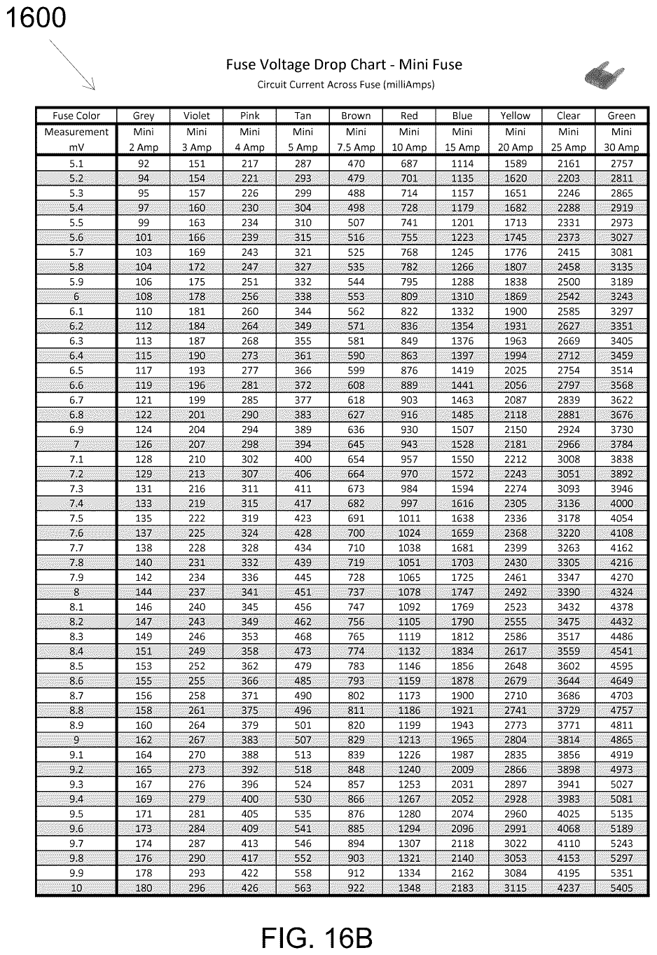

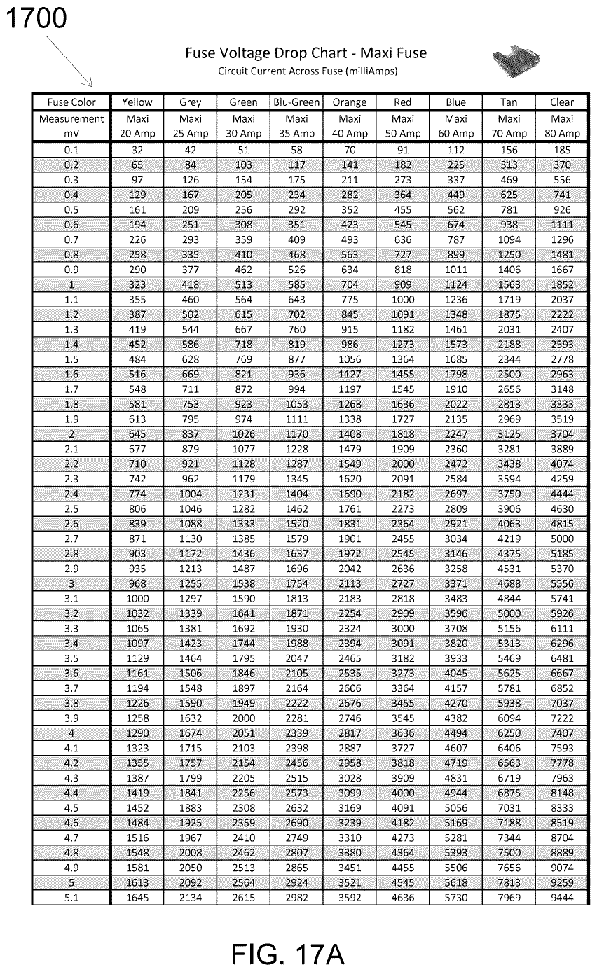

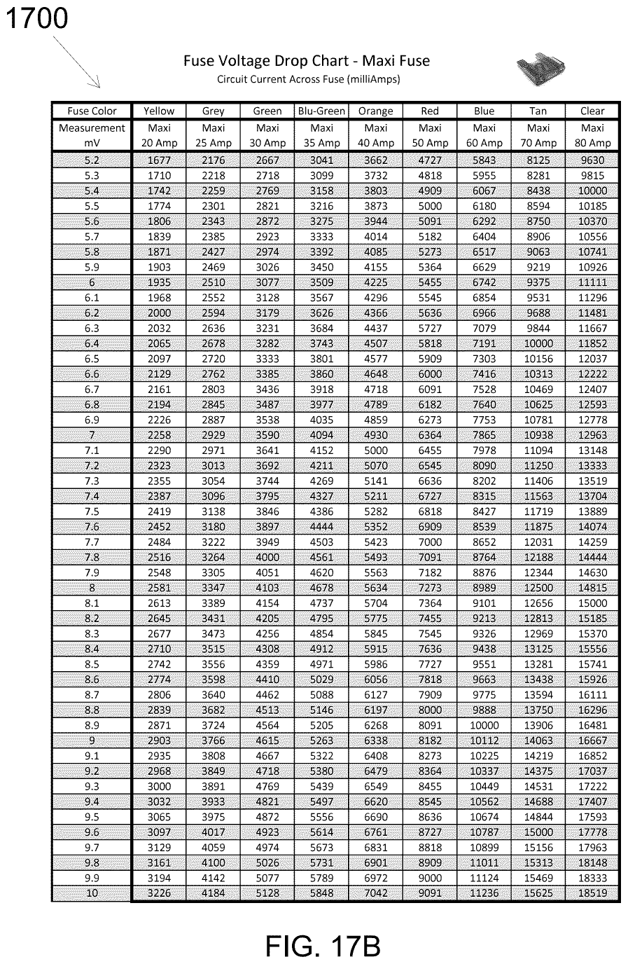

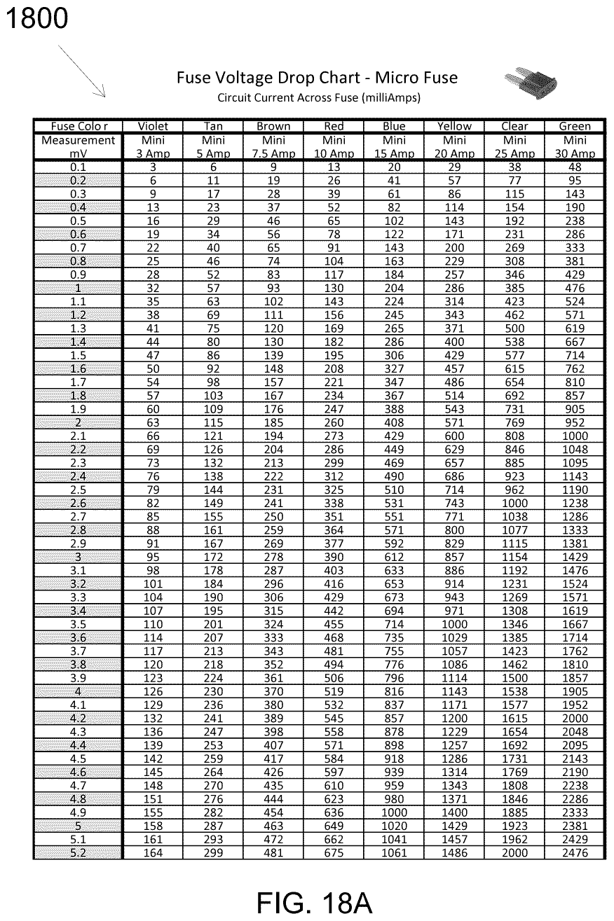

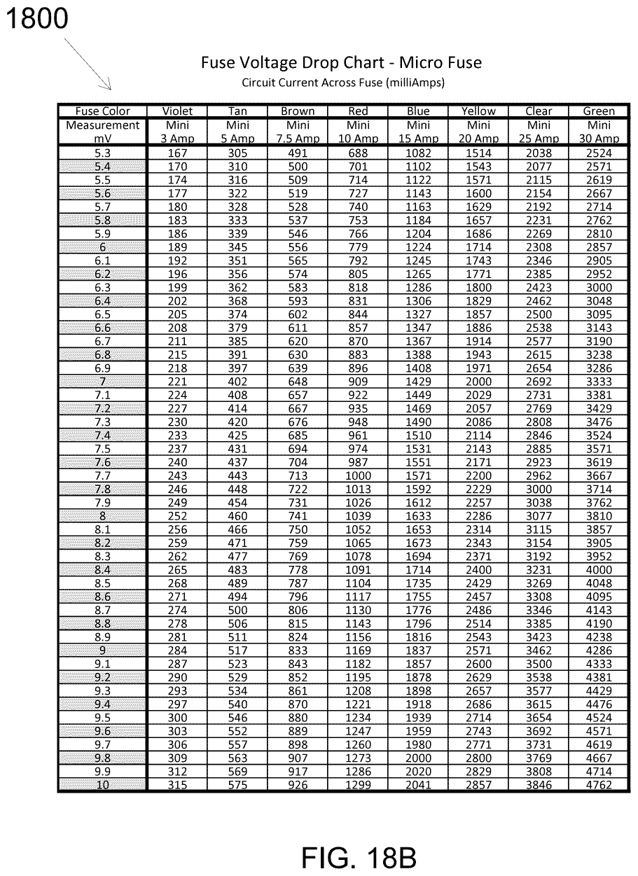

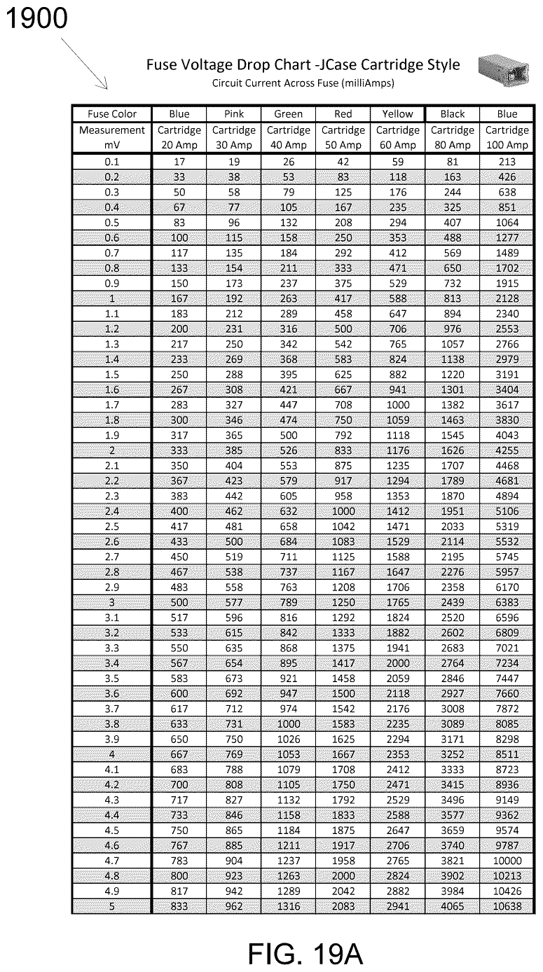

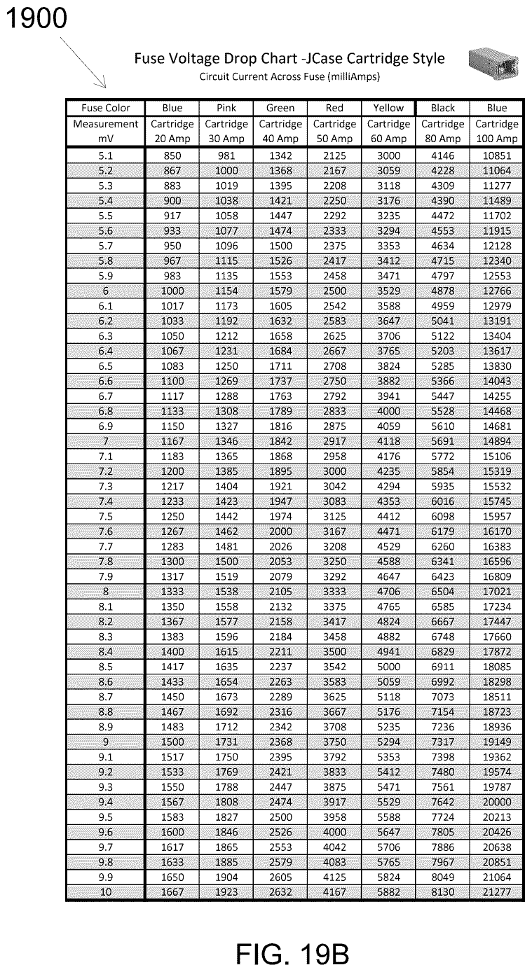

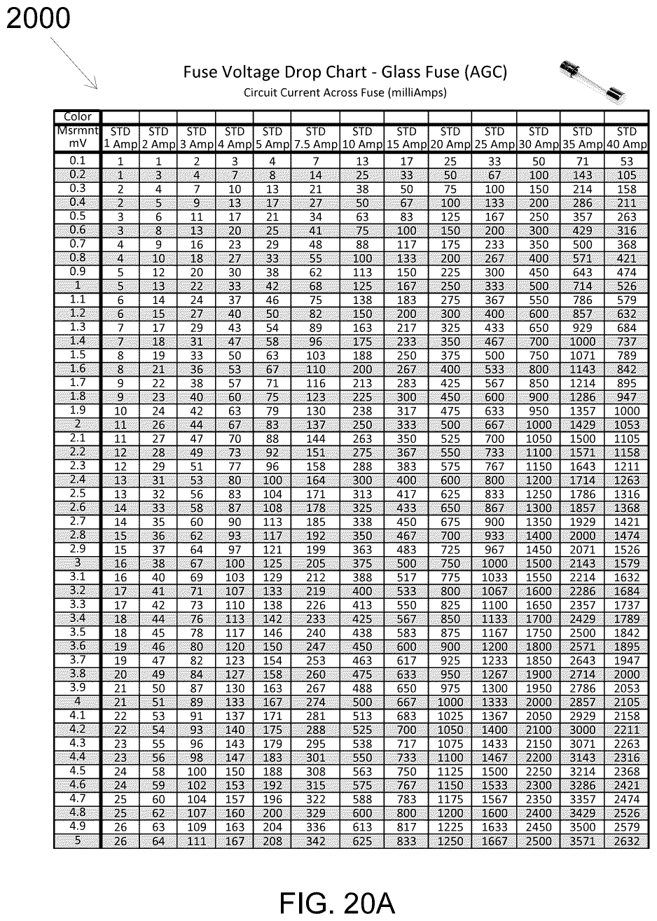

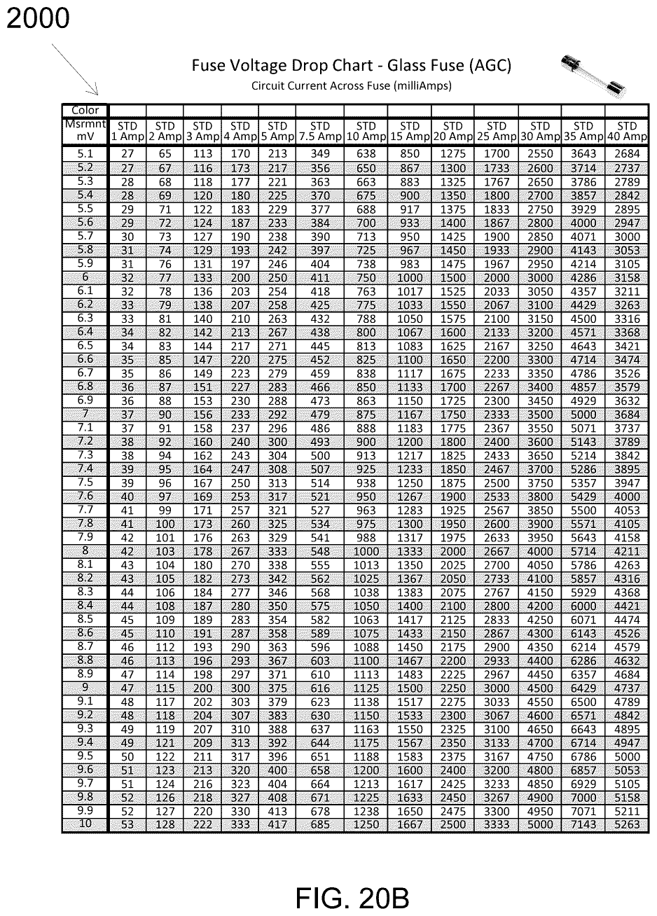

Specifically, the impedance data includes a plurality of voltage drop charts, and a user may toggle/scroll through each of the voltage drop charts to select the appropriate electrical element being detected and/or measured. Data of each of the voltage drop charts depicted by FIGS. 15A-20B would be stored to the data storage location. Specifically, the fuse voltage drop charts include impedance data for a standard fuse, a mini fuse, a maxi fuse, a micro fuse. In addition, a user is able to select the fuse value within each fuse type in order to select the corresponding impedance for the fuse type and fuse value. FIGS. 15A-15B depict portions of a fuse voltage drop chart 1500 for a standard fuse, according to one embodiment of the present invention. FIGS. 16A-16B depict portions of a fuse voltage drop chart 1600 of a mini fuse, according to one embodiment of the present invention. FIGS. 17A-17B depict portions of a fuse voltage drop chart 1700 of a maxi fuse, according to one embodiment of the present invention. FIGS. 18A-18B depict portions of a fuse voltage drop chart 1800 of a micro fuse, according to one embodiment of the present invention. FIGS. 19A-19B depict portions of a fuse voltage drop chart 1900 of a JCASE™ cartridge style fuse, according to one embodiment of the present invention. FIGS. 20A-20B depict portions of a fuse voltage drop chart 2000 of a glass fuse, according to one embodiment of the present invention.

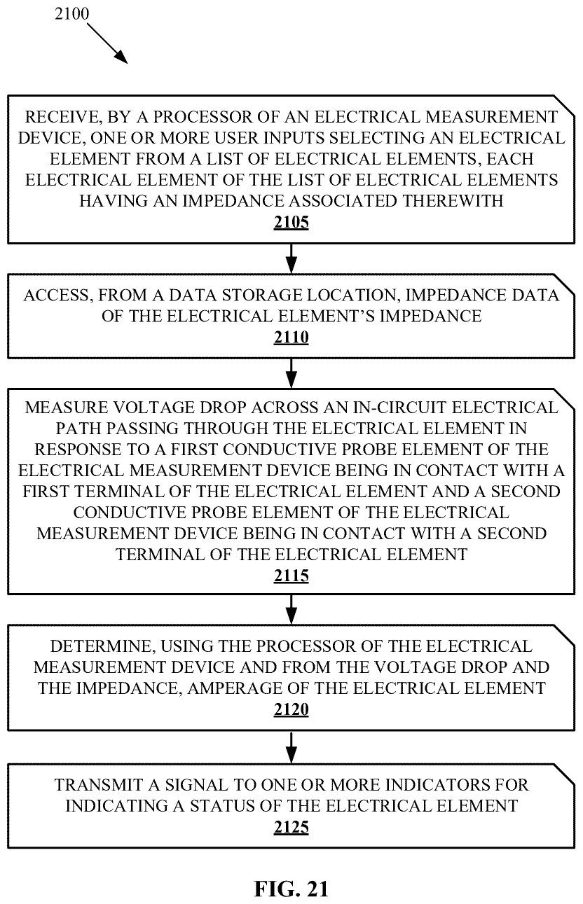

FIG. 21 depicts a block diagram of an example method 2100, according to an implementation of the present disclosure. At block 2105, the system receives, by a processor of an electrical testing device, one or more user inputs selecting an electrical element from a list of electrical elements, each electrical element of the list of electrical elements having an impedance associated therewith. In some embodiments, the electrical element includes a vehicle fuse, the first terminal is a first fuse terminal, and the second terminal is a second fuse terminal. In some embodiments, the electrical testing device includes a first input for selecting a mode associated with the electrical element, a second input for turning on or off a light emitting diode (LED), and a third input for adjusting the brightness of the backlight of the display screen. In some embodiments, a front face of a housing of the electrical testing device includes a lighting element directed towards the first conductive probe element and the second terminal of the electrical element.

At block 2110, the system accesses, from a data storage location, impedance data of the electrical element's impedance. In some embodiments, the data storage location includes a database internal to the electrical testing device. At block 2115, the system detects and/or measures voltage drop across an in-circuit electrical path passing through the electrical element in response to a first conductive probe element of the electrical testing device being in contact with a first terminal of the electrical element and a second conductive probe element of the electrical testing device being in contact with a second terminal of the electrical element. In some embodiments, the first conductive probe element of the electrical testing device and the second conductive probe element of the electrical testing device are both at least partially integrated with the electrical testing device itself.

At block 2120, the system determines, using the processor of the electrical testing device and from the voltage drop and the impedance, amperage of the electrical element, and at block 2125, a signal is transmitted to one or more indicators for indicating a status of the electrical element. In some embodiments, the method 2100 further includes displaying, via a user interface of the electrical element, a numerical value of the amperage of the electrical element. In some embodiments, the one or more indicators include one or more indicator lights, where the one or more indicator lights provide a visual indication of the status of the electrical element, the status being selected from the group consisting of “Inactive,” “Active,” and “Broken.” In some embodiments, the one or more indicator lights incorporate a color-specific indication where a green color is associated with the “Inactive” status, a white/yellow color is associated with the “Active” status, and a red color is associated with the “Broken” status.

In some embodiments, an electronic testing instrument may incorporate an electric multimeter in combination with a meter pen box, where the electric multimeter and the meter pen box each include at least four interconnected connection points (e.g., terminals, holes, etc.) where the different interconnected connection points form different functions. For example, one connection point may provide a grounding functionality, another connection point may be used to detect and/or measure a relatively higher current amperage (e.g., 10 A), another connection point may be used to detect and/or measure a relatively lower current amperage (e.g., 1 A), and another connection point may be used to create a composite measurement. The meter pen box may supplement the capabilities of the electric multimeter in order to provide a maximum detection and/or measurement current of 30 A. The meter pen box may include modifiable current detection and/or measurement modes through a logic circuit.

In this embodiment, an electronic testing instrument (e.g., the meter pen box in combination with the multimeter) may detect and/or measure voltage drop across an electrical path passing through an electrical element in response to a first conductive probe element of the electrical testing device being in contact with a first terminal of the electrical element and a second conductive probe element of the electrical testing device being in contact with a second terminal of the electrical element. The electronic testing instrument determines from the voltage drop and an impedance value selected from one or more stored impedance values, amperage of the electrical element. An alert message may be transmitted to one or more communication interfaces for providing an indication of the amperage of the electrical element.

In some embodiments, systems and methods of identifying amperage includes determining voltage drop across an in-circuit electrical path passing through an electrical element in response to a first conductive probe element that is coupled to an electrical testing device being in contact with a first terminal of the electrical element and a second conductive probe element that is coupled to the electrical testing device being in contact with a second terminal of the electrical element. Further, the method includes determining, using a processor of the electrical testing device and from the voltage drop and from a stored impedance value corresponding to the electrical element, amperage of the electrical element. The method also includes transmitting a signal to one or more communication interfaces for communicating the amperage. In some embodiments, the range of the amperage is between 0 A-100 A, and more particularly between 0 A-80 A or between 0 A-30 A. In some embodiments, the stored impedance value is selected from impedance data of a plurality of impedance values stored to one or more data storage locations. Further, the stored impedance value may be selected based on receiving one or more user inputs identifying the electrical element.

Disclosed herein are methods that include powering, via a power supply, an electrical system, and based thereon performing, via a first electrical device, selective detection and/or measurement of at least two parameters of the electrical system, the powering being selectively provided during detection and/or measurement of the at least two parameters. In some instances, the power supply used by the first electrical device is external to the first electrical device. The first electrical device may include a probe element that is configured to be placed into contact with the electrical system and provide an input signal thereto and a processor electrically connected to the conducting probe element and configured to (a) manipulate the input signal provided to the electrical system, and (b) receive an output signal representative of one or more parameters of the at least two parameters of the electrical system. The method may also include detecting, via one or more sensors of a second electrical device and based on the second electrical device being coupled to the electrical system, presence of at least one parameter and/or flow of the at least one parameter from the power supply to the electrical system, the second electrical device including an analyzer electrically coupled to the one or more sensors and configured to derive parasitic draw of the electrical system based on the detection of the at least one parameter. The second electrical device Further, the method may include preserving, via the second electrical device, memory settings of the electrical system, and deriving, via the analyzer of the second electrical device, the parasitic draw of the electrical system from the parameter flowing from the power supply to the electrical system.

The method may also include receiving, by a third electrical device, one or more user inputs selecting an electrical element from a list of electrical elements, each electrical element of the list of electrical elements having an impedance associated therewith, and accessing, from a data storage location associated with the third electrical device, impedance data of the electrical element's impedance. The method may also include determining, via the third electrical device, voltage drop across an in-circuit electrical path passing through the electrical element, and determining, via the third electrical device and from the voltage drop and the impedance, amperage of the electrical element.

In one embodiment, the at least two parameters include at least one of circuit continuity, resistance, voltage, current, load impedance, and frequency. In one embodiment, the electrical system is disconnected from a power source of the electrical system when the second power supply of the second electrical device provides power. For example, the power source may be a vehicle battery of a vehicle and the electrical system is associated with the vehicle. In one embodiment, the method further includes transmitting, via a wireless network and by a wireless communication means, one or more outputs of at least one of the first electrical device, the second electrical device and the third electrical device. In one embodiment, the parameter flowing from the power supply to the electrical system is current flow. In one embodiment, the method further includes displaying, via an interface of the second electrical device, a graphical representation of changes in the current flow and a measured voltage being transmitted from the power supply to the electrical system, the graphical representation of the changes being depicted over a period of time in which the current flow and the measured voltage are being detected. In some embodiments, the second electrical device includes an interface that comprises a sixteen-pin connection, where the interface is coupled to the electrical system via a diagnostic port. In some embodiments, the electrical element includes a vehicle fuse.

Also disclosed herein is an electrical testing method that includes using a first electrical device to detect and/or measure at least two parameters of an electrical system, where the first electrical device includes a probe element that is configured to be placed into contact with the electrical system and provide an input signal thereto, and a processor electrically connected to the conducting probe element and configured to (a) manipulate the input signal provided to the electrical system, and (b) receive an output signal representative of one or more parameters of the at least two parameters of the electrical system. The method also includes using a second electrical device to (i) preserve memory settings of the electrical system, and (ii) derive any parasitic draw within the electrical system. Further, the method includes using a third electrical device to derive amperage of an electrical element of the electrical system, the deriving determining voltage drop across an in-circuit electrical path passing through the electrical element and accessing impedance data of the electrical element to calculate from the voltage drop and the impedance data amperage of the electrical element.

An electrical testing system is also disclosed, where the system includes a first electrical device to detect and/or measure at least two parameters of an electrical system. The first electrical device includes a probe element that is configured to be placed into contact with the electrical system and provide an input signal thereto and a processor electrically connected to the conducting probe element and configured to (a) manipulate the input signal provided to the electrical system, and (b) receive an output signal representative of one or more parameters of the at least two parameters of the electrical system. The system also includes a second electrical device for (i) preserving memory settings of the electrical system, and (ii) deriving any parasitic draw within the electrical system. The second electrical device includes a power supply for providing power to the electrical system, which enables the second electrical device to maintain memory of electrical system settings during disconnect of a power source of the electrical system and one or more sensors for detecting presence of at least one parameter and/or flow of the at least one parameter from the power supply of the second electrical device to the electrical system. The second electrical device also includes an analyzer electrically coupled to the one or more sensors and configured to derive parasitic draw of the electrical system based on the detection and/or measurement of the at least one parameter. The system also includes a third electrical device for determining amperage of an electrical element of the electrical system. The third electrical device includes a first conductive probe element, a second conductive probe element, a processor in electrical communication with the first conductive probe element and the second conductive probe element, and a data storage location storing impedance data for a list of electrical elements, the list of electrical elements including the electrical element of the electrical system.

In some embodiments, the electrical element includes a vehicle fuse. In some embodiments, the at least two parameters include at least one of circuit continuity, resistance, voltage, current, load impedance, and frequency. In one embodiment, the power source is a vehicle battery of a vehicle and the electrical system is associated with the vehicle. In one embodiment, the parameter flowing from the power supply of the second electrical device to the electrical system includes at least one of a current flow and a measured voltage. In one embodiment, the third electrical device further includes a first input for selecting a mode associated with the electrical element, a second input for turning on or off a light emitting diode (LED) of the third electrical device, and a third input for adjusting the brightness of the backlight of a display screen of the third electrical device. In one embodiment, the third electrical device further includes at least two visual indicators for indicating a status of the electrical element.

Also disclosed herein is an electrical testing kit. The kit includes a first electrical device to testing at least two parameters of an electrical system. Further, the first electrical device includes a probe element that is configured to be placed into contact with the electrical system and provide an input signal thereto and a processor electrically connected to the conducting probe element and configured to (a) manipulate the input signal provided to the electrical system, and (b) receive an output signal representative of one or more parameters of the at least two parameters of the electrical system. The kit also includes a second electrical device for (i) preserving memory settings of the electrical system, and (ii) deriving any parasitic draw within the electrical system. The second electrical device includes a power supply for providing power to the electrical system, which enables the second electrical device to maintain memory of electrical system settings during disconnect of a power source of the electrical system, one or more sensors for detecting a parameter flowing from the power supply of the second electrical device to the electrical system, and an analyzer electrically coupled to the one or more sensors and configured to derive parasitic draw of the electrical system based on the detection and/or measurement of the parameter. The kit also includes a third electrical device for determining amperage of an electrical element of the electrical system. The third electrical device includes a first conductive probe element, a second conductive probe element, a processor in electrical communication with the first conductive probe element and the second conductive probe element, and a data storage location storing impedance data for a list of electrical elements, the list of electrical elements including the electrical element of the electrical system. In some embodiments, the electrical element includes a vehicle fuse and the at least two parameters include at least one of circuit continuity, resistance, voltage, current, load impedance, and frequency.

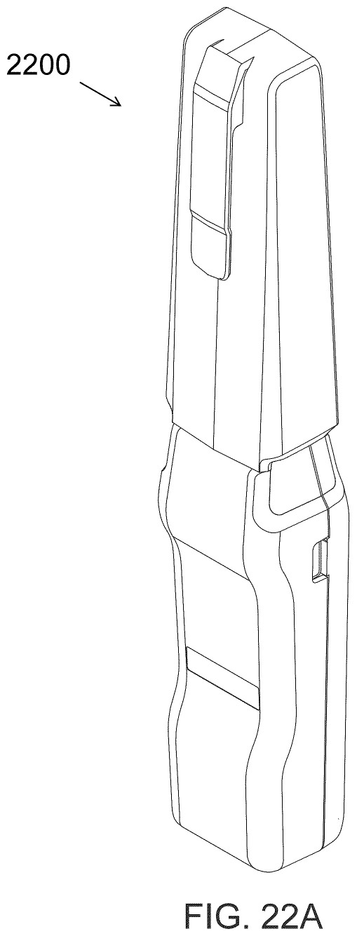

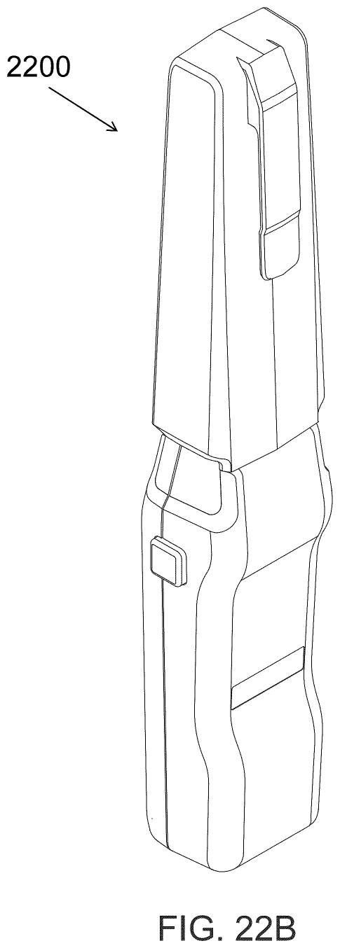

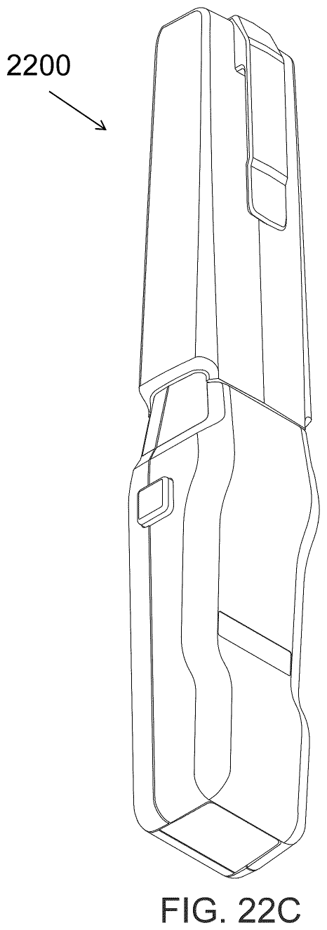

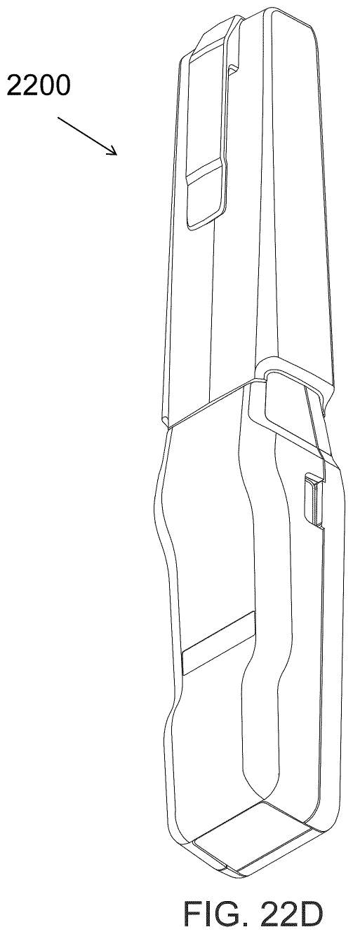

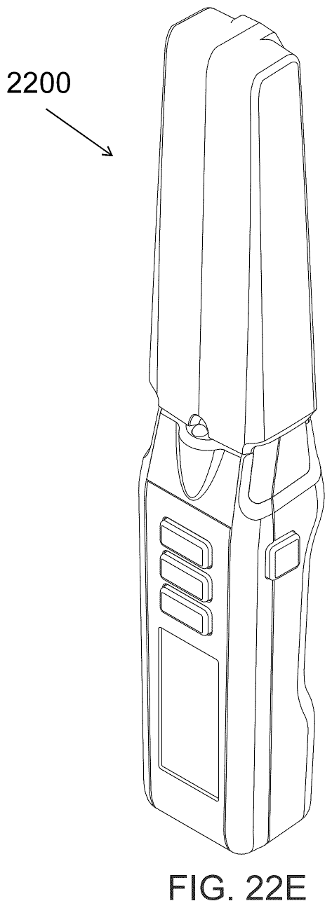

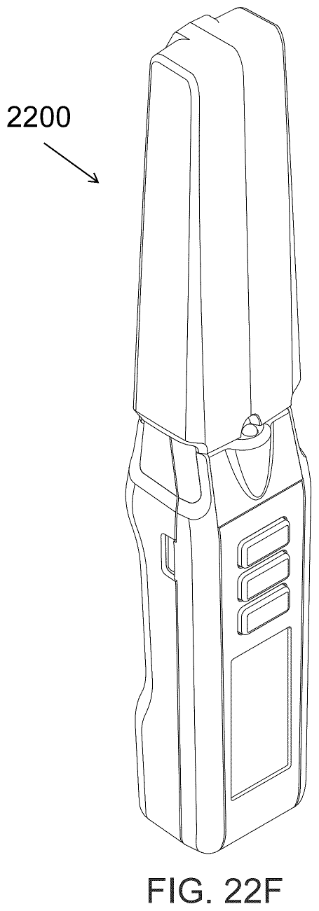

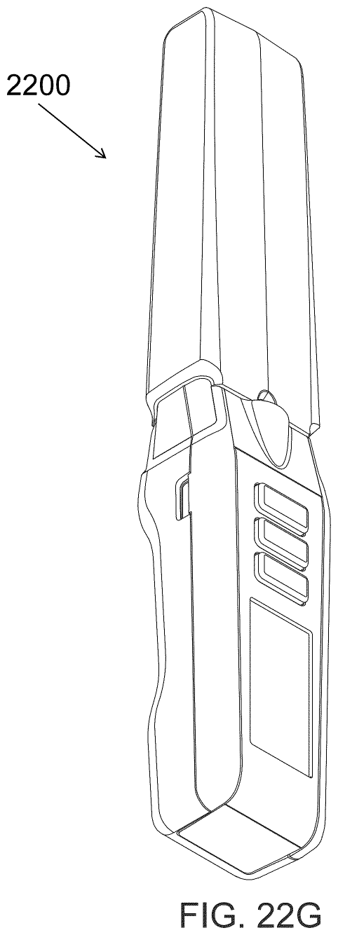

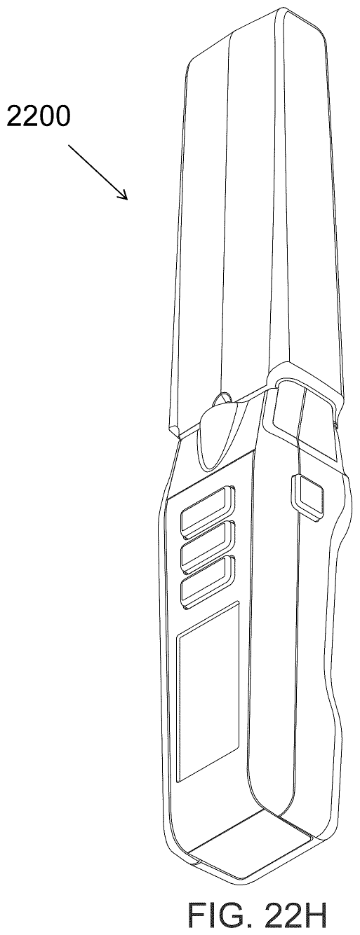

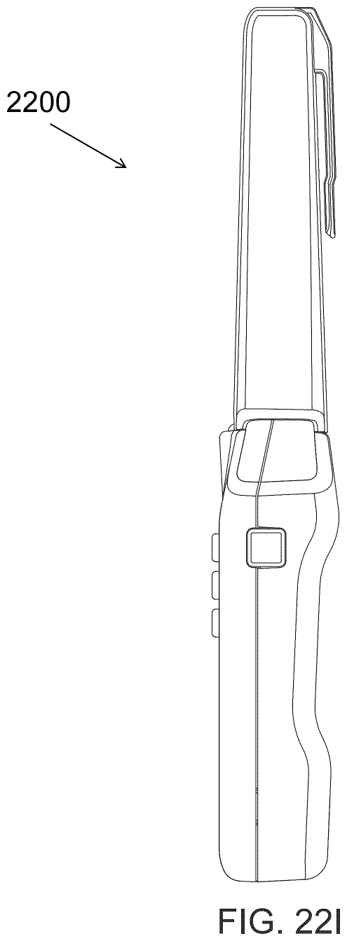

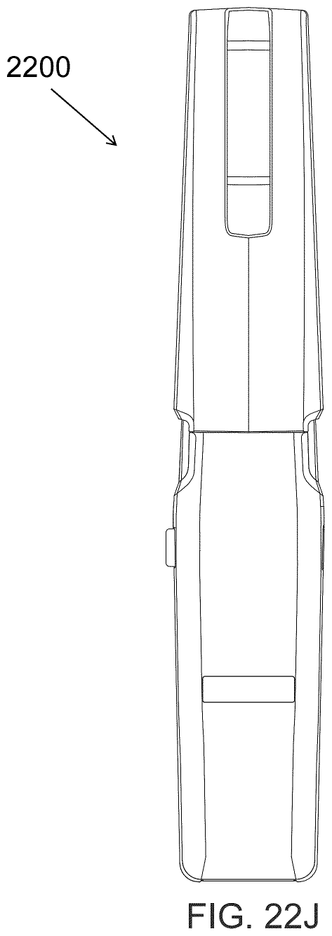

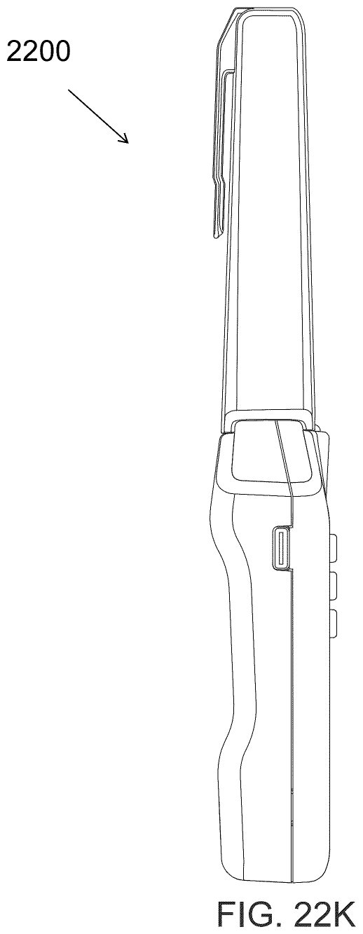

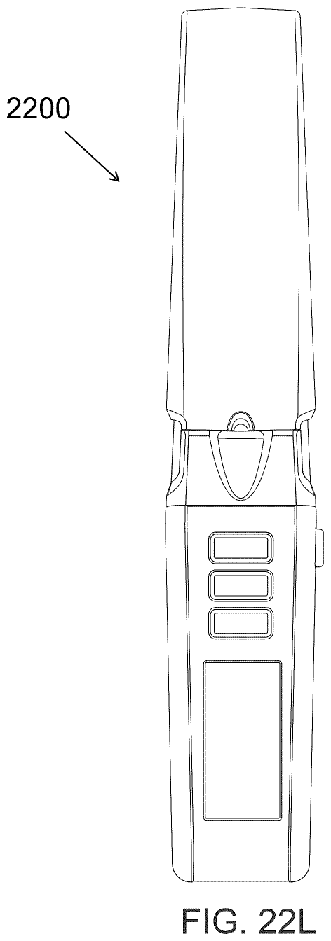

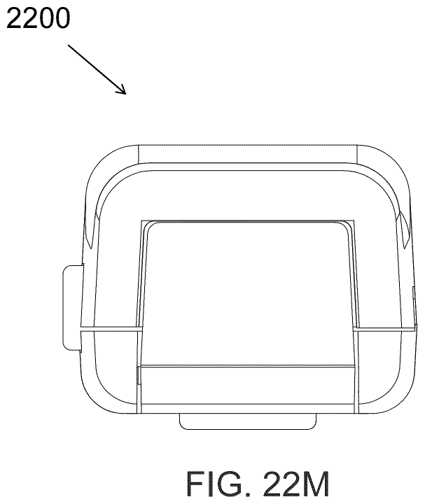

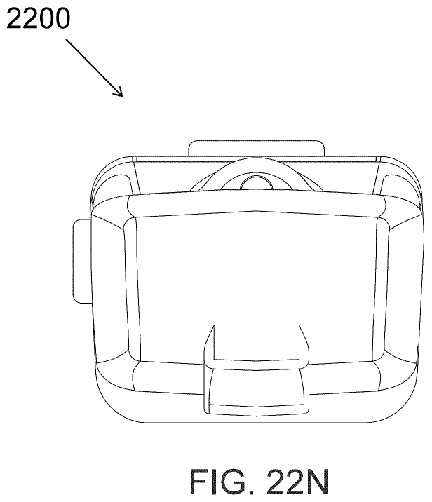

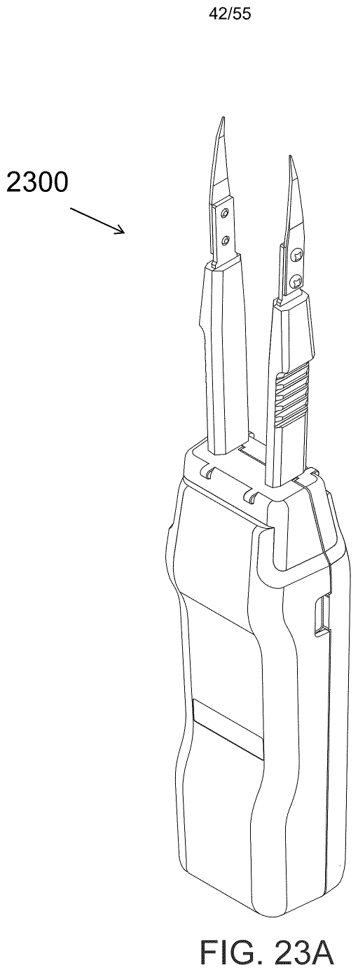

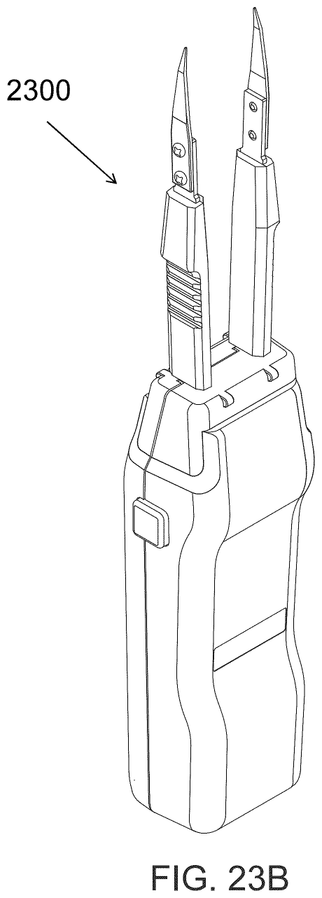

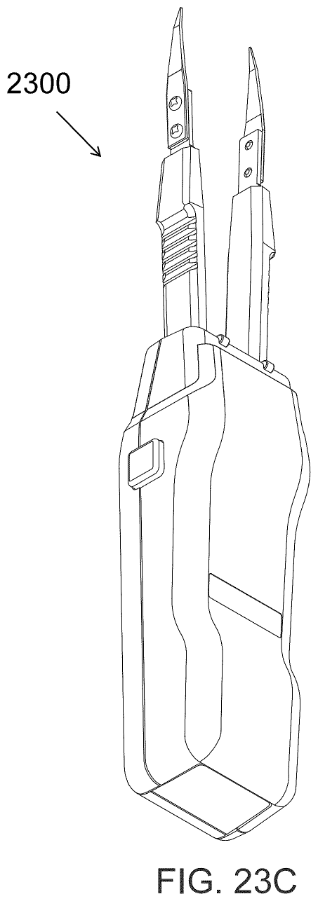

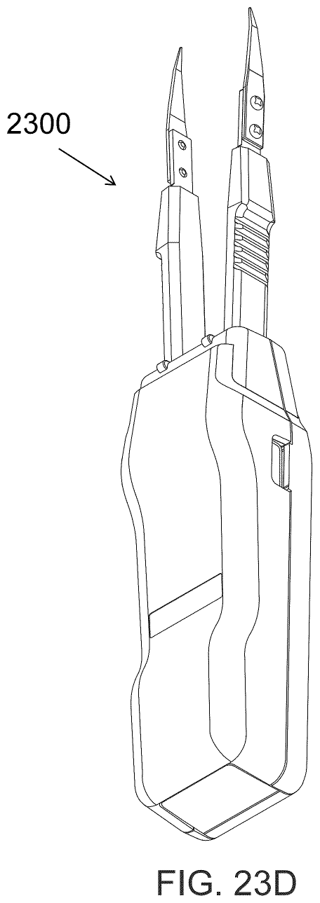

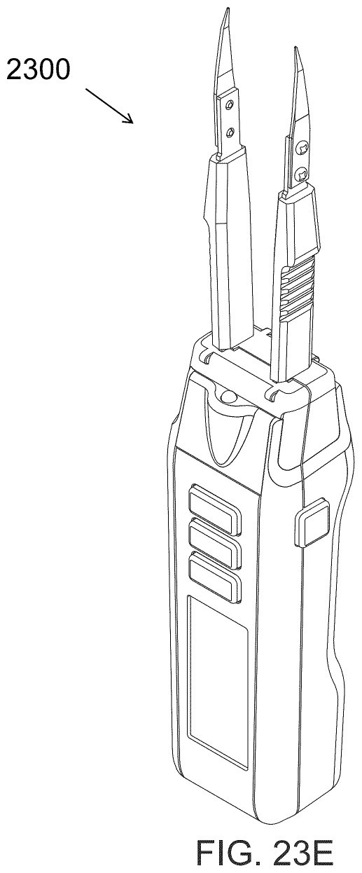

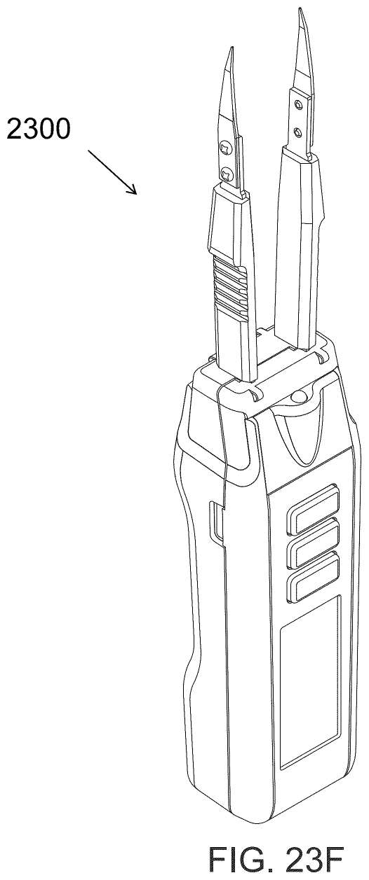

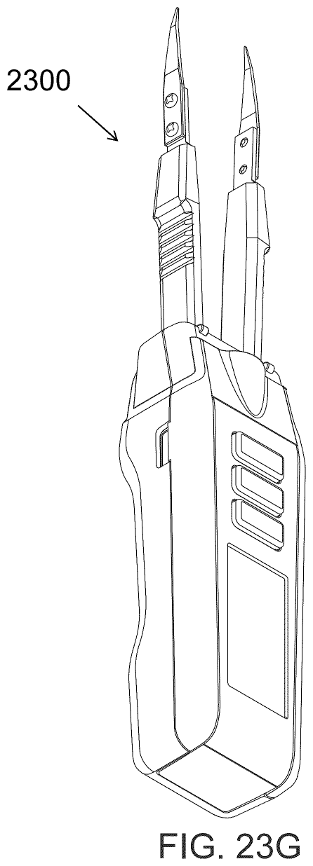

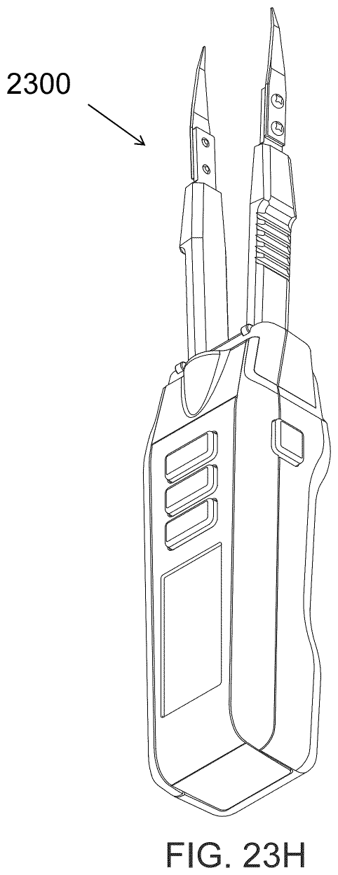

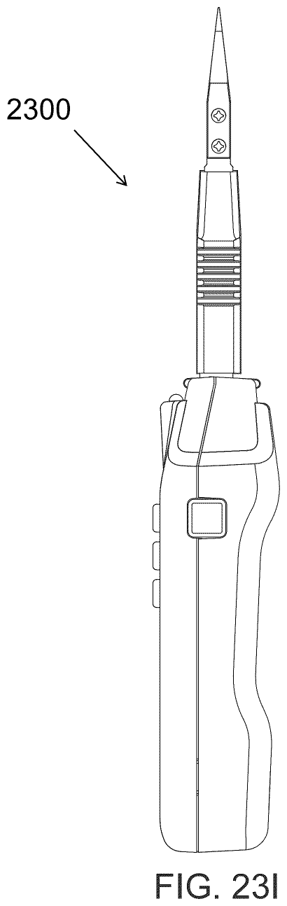

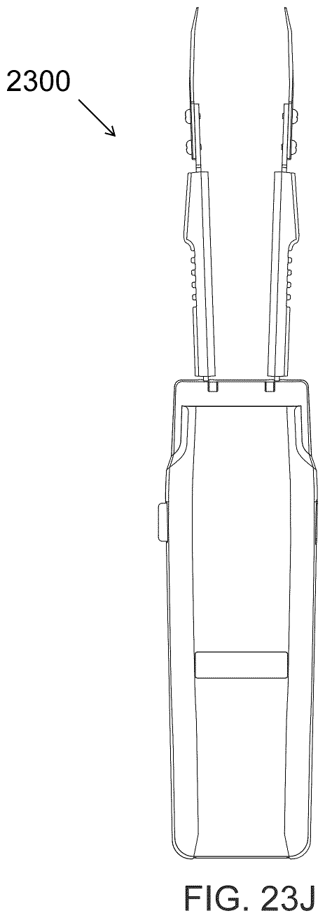

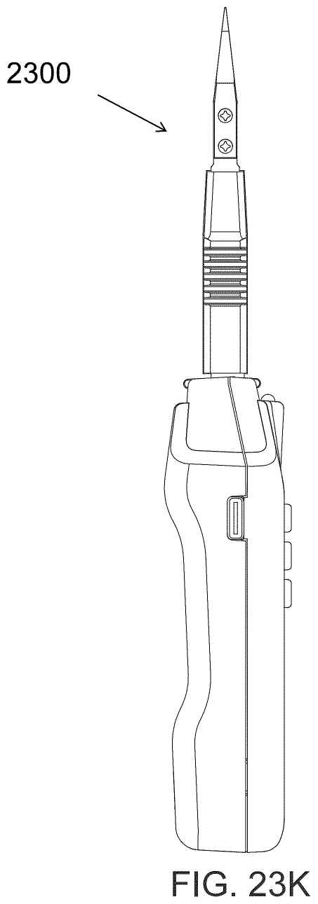

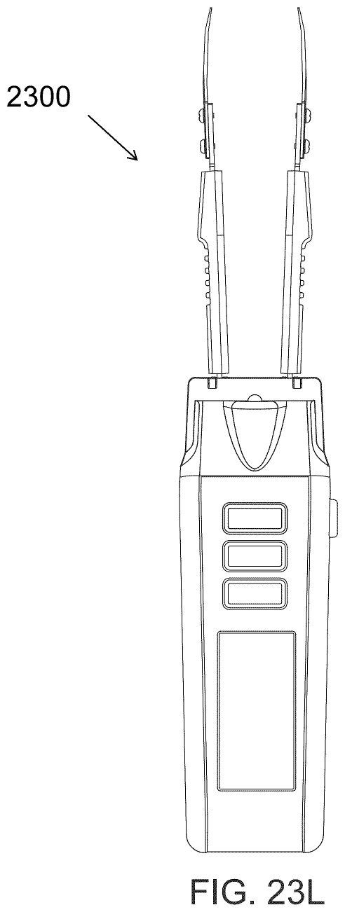

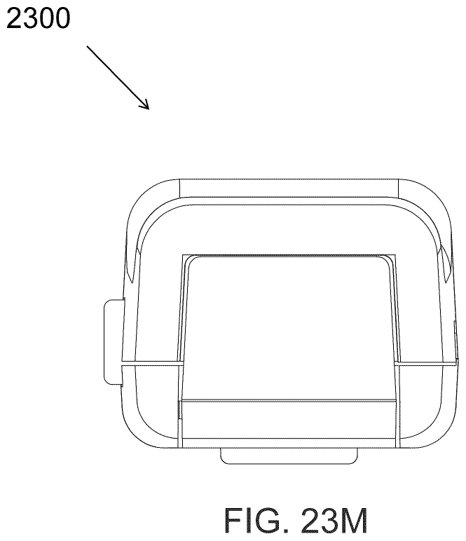

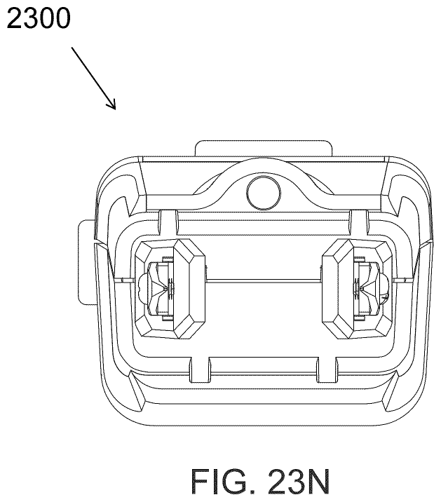

FIGS. 22A-22N depict various views of an electrical testing device 2200 in combination with a sleeve, according to an implementation of the present disclosure. FIGS. 23A-23N depict various views of an electrical testing device 2300, according to an implementation of the present disclosure.

Flowcharts and block diagrams depicted in the figures may illustrate functionality and operation of possible implementations of various apparatuses, systems, and methods, according to various embodiments of the present invention. In this regard, each block in the flowcharts and block diagrams may incorporate a specific function or portion of a function. Additionally, the flowcharts and block diagrams may incorporate alternative implementations and the functions noted in the block diagram may occur in a different order from that noted in the figures. For example, two blocks shown in succession may, in fact, be executed substantially concurrently, or the functions noted in the blocks may be implemented in reverse order depending on the functionality involved.

The terminology used herein is for describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises,” “has,” “includes,” or “contains” one or more steps or elements possesses those one or more steps or elements but is not limited to possessing only those one or more steps or elements. Likewise, a step of a method or an element of a device that “comprises,” “has,” “includes,” or “contains” one or more features possesses those one or more features but is not limited to possessing only those one or more features. Furthermore, a device or structure that is configured in a certain way is configured in at least that way but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiments were chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. An electrical testing method, comprising:
powering, via a first power supply, an electrical system, and based thereon performing, via a first electrical device, selective detection of at least two parameters of the electrical system, the powering being selectively provided during detection of the at least two parameters, the first electrical device including:
a probe element that is configured to be placed into contact with the electrical system and provide an input signal thereto;
a processor electrically connected to the conducting probe element and configured to (a) manipulate the input signal provided to the electrical system, and (b) receive an output signal representative of one or more parameters of the at least two parameters of the electrical system;
determining, via one or more sensors of a second electrical device and based on the second electrical device being coupled to the electrical system, presence of at least one parameter and/or flow of the at least one parameter from a second power supply to the electrical system, the second electrical device including an analyzer electrically coupled to the one or more sensors and configured to derive parasitic draw of the electrical system based on the determination of the at least one parameter;
preserving, via the second electrical device, memory settings of the electrical system;
deriving, via the analyzer of the second electrical device, the parasitic draw of the electrical system from the at least one parameter flowing from the second power supply to the electrical system;
receiving, by a third electrical device, one or more user inputs selecting an electrical element from a list of electrical elements, each electrical element of the list of electrical elements having an impedance associated therewith;
accessing, from a data storage location associated with the third electrical device, impedance data of the electrical element's impedance;
determining, via the third electrical device, voltage drop across an in-circuit electrical path passing through the electrical element;
determining, via the third electrical device and from the voltage drop and the impedance, amperage of the electrical element.

2. The method of claim 1, wherein the at least two parameters include at least one of circuit continuity, resistance, voltage, current, load impedance, and frequency.

3. The method of claim 1, wherein the electrical system is disconnected from a power source of the electrical system when the second power supply of the second electrical device provides power.

4. The method of claim 3, wherein the power source is a vehicle battery of a vehicle and the electrical system is associated with the vehicle.

5. The method of claim 1, further comprising transmitting, via a wireless network and by a wireless communication means, one or more outputs of at least one of the first electrical device, the second electrical device and the third electrical device.

6. The method of claim 1, wherein the at least one parameter flowing from the second power supply to the electrical system is current.

7. The method of claim 6, displaying, via an interface of the second electrical device, a graphical representation of changes in the current and a measured voltage being transmitted from the second power supply to the electrical system, the graphical representation of the changes being depicted over a period of time in which the current and the measured voltage are being measured.

8. The method of claim 1, wherein the second electrical device includes an interface that comprises a sixteen-pin connection, where the interface is coupled to the electrical system via a diagnostic port.

9. The method of claim 1, wherein the electrical element includes a vehicle fuse.

10. An electrical testing method, comprising:
using a first electrical device to detect at least two parameters of an electrical system, the first electrical device including:
a probe element that is configured to be placed into contact with the electrical system and provide an input signal thereto;
a processor electrically connected to the conducting probe element and configured to (a) manipulate the input signal provided to the electrical system, and (b) receive an output signal representative of one or more parameters of the at least two parameters of the electrical system;
using a second electrical device to (i) preserve memory settings of the electrical system, and (ii) derive any parasitic draw within the electrical system;
using a third electrical device to derive amperage of an electrical element of the electrical system, the deriving determining voltage drop across an in-circuit electrical path passing through the electrical element and accessing impedance data of the electrical element to calculate from the voltage drop and the impedance data amperage of the electrical element.

11. An electrical testing system, comprising:
a first electrical device to detect at least two parameters of an electrical system, the first electrical device comprising:
a probe element that is configured to be placed into contact with the electrical system and provide an input signal thereto;
a processor electrically connected to the conducting probe element and configured to (a) manipulate the input signal provided to the electrical system, and (b) receive an output signal representative of one or more parameters of the at least two parameters of the electrical system;
a second electrical device for (i) preserving memory settings of the electrical system, and (ii) deriving any parasitic draw within the electrical system, the second electrical device comprising:
a first power supply for providing power to the electrical system, which enables the second electrical device to maintain memory of electrical system settings of the electrical system during disconnect of a power source of the electrical system;
one or more sensors for detecting presence of at least one parameter and/or flow of the at least one parameter from a power supply of the second electrical device to the electrical system;
an analyzer electrically coupled to the one or more sensors and configured to derive parasitic draw of the electrical system based on the detection of the at least one parameter;
a third electrical device for determining amperage of an electrical element of the electrical system, the third electrical device comprising:
a first conductive probe element;
a second conductive probe element;
a processor in electrical communication with the first conductive probe element and the second conductive probe element; and
a data storage location storing impedance data for a list of electrical elements, the list of electrical elements including the electrical element of the electrical system.

12. The electrical testing system of claim 11, wherein the electrical element includes a vehicle fuse.

13. The electrical testing system of claim 11, wherein the at least two parameters include at least one of circuit continuity, resistance, voltage, current, load impedance, and frequency.

14. The electrical testing system of claim 11, wherein the power source is a vehicle battery of a vehicle and the electrical system is associated with the vehicle.

15. The electrical testing system of claim 11, wherein the at least one parameter includes at least one of a current and a measured voltage.

16. The electrical testing system of claim 11, wherein the third electrical device further includes a first input for selecting a mode associated with the electrical element, a second input for turning on or off a light emitting diode (LED) of the third electrical device, and a third input for adjusting the brightness of the backlight of a display screen of the third electrical device.

17. The electrical testing system of claim 11, wherein the third electrical device further includes at least two visual indicators for indicating a status of the electrical element.

18. An electrical testing kit, comprising:
a first electrical device to detect at least two parameters of an electrical system, the first electrical device comprising:
a probe element that is configured to be placed into contact with the electrical system and provide an input signal thereto;
a processor electrically connected to the conducting probe element and configured to (a) manipulate the input signal provided to the electrical system, and (b) receive an output signal representative of one or more parameters of the at least two parameters of the electrical system;
a second electrical device for (i) preserving memory settings of the electrical system, and (ii) deriving any parasitic draw within the electrical system, the second electrical device comprising:
a power supply for providing power to the electrical system, which enables the second electrical device to maintain memory of electrical system settings of the electrical system during disconnect of a power source of the electrical system;
one or more sensors for detecting presence of at least one parameter and/or flow of the at least one parameter from the power supply of the second electrical device to the electrical system;
an analyzer electrically coupled to the one or more sensors and configured to derive parasitic draw of the electrical system based on the detection of the one or more parameters;
a third electrical device for determining amperage of an electrical element of the electrical system, the third electrical device comprising:
a first conductive probe element;
a second conductive probe element;
a processor in electrical communication with the first conductive probe element and the second conductive probe element; and
a data storage location storing impedance data for a list of electrical elements, the list of electrical elements including the electrical element of the electrical system.

19. The electrical testing kit of claim 18, wherein the electrical element includes a vehicle fuse.

20. The electrical testing kit of claim 18, wherein the at least two parameters include at least one of circuit continuity, resistance, voltage, current, load impedance, and frequency.
